(19) United States
(12) Patent Application Publication
(10) Pub. No.: US 2015/0082118 A1
(43) Pub. Date: Mar. 19, 2015

(54) TRANSMITTING APPARATUS AND PUNCTURING METHOD THEREOF

(71) Applicant: SAMSUNG ELECTRONICS CO., LTD., Suwon-si (KR)

(72) Inventors: Hong-sil JEONG, Suwon-si (KR); Se-ho MYUNG, Yongin-si (KR); Kyung-joong KIM, Seoul (KR)

(73) Assignee: SAMSUNG ELECTRONICS CO., LTD., Suwon-si (KR)

(21) Appl. No.: 14/489,930

(22) Filed: Sep. 18, 2014

Related U.S. Application Data
(60) Provisional application No. 61/882,721, filed on Sep. 26, 2013.
(60) Provisional application No. 61/882,213, filed on Sep. 25, 2013.
(60) Provisional application No. 61/879,262, filed on Sep. 18, 2013.

(30) Foreign Application Priority Data
Sep. 18, 2014 (KR) 10-2014-0124544

(51) Int. Cl. H03M 13/11; H03M 13/00

(52) U.S. Cl. CPC H03M 13/1102; H03M 13/611
USPC 714/758

(57) ABSTRACT

Provided are a transmitting apparatus, a receiving apparatus and methods of puncturing and depuncturing of parity bits. The transmitting apparatus includes: a zero padder configured to pad at least one zero bit to input bits; an encoder configured to generate a Low Density Parity Check (LDPC) codeword by performing LDPC encoding with respect to the bits to which the at least one zero bit is padded; a parity interleaver configured to interleave LDPC parity bits constituting the LDPC codeword; and a puncturer configured to puncture at least a part of the interleaved LDPC parity bits based on a pre-set puncturing pattern.

### CROSS-REFERENCE TO RELATED APPLICATIONS

This application claims the benefit under 35 U.S.C. §119 from U.S. Provisional Application No. 61/882,721 filed on Sep. 26, 2013, U.S. Provisional Application No. 61/882,213 filed on Sep. 25, 2013, and U.S. Provisional Application No. 61/879,262 field on Sep. 18, 2013, and Korean Patent Application No. 10-2014-0124544 field on Sep. 18, 2014, in the Korean Intellectual Property Office, the disclosure of which is incorporated herein by reference in its entirety.

### BACKGROUND

1. Field

Apparatuses and methods consistent with exemplary embodiments relate to a transmitting apparatus and a puncturing method thereof, and more particularly, to a transmitting apparatus which punctures at least some parity bit and transmits the punctured bits, and a puncturing method thereof.

2. Description of the Related Art

In the 21^{st} century information-oriented society, broadcasting communication services are moving into the era of digitalization, multi-channel, wideband, and high quality. In particular, as high quality digital televisions and portable multimedia players and portable broadcasting equipment are increasingly used in recent years, there is an increasing demand for various methods for receiving digital broadcasting services.

The standard group has established various standards to meet such a demand and is providing a variety of services to satisfy the user's needs. However, there is still a demand for a method for providing improved services to users.

In particular, when a transmitting side which provides a digital broadcasting service punctures some parities included in a broadcasting signal, performance of a codeword of the signal greatly depends on which bits are punctured. In this regard, a method for selecting bits to be punctured may be considered to maintain optimal performance of transmission and reception of the broadcasting signal.

### SUMMARY

One or more exemplary embodiments may overcome the above disadvantages and other disadvantages not described above. However, it is understood that one or more exemplary embodiment are not required to overcome the disadvantages described above, and may not overcome any of the problems described above.

One or more exemplary embodiments provide a transmitting apparatus which punctures at least some Low Density Parity Check (LDPC) parity bits based on a puncturing pattern to improve decoding performance at a receiving side, and a puncturing method thereof.

According to an aspect of an exemplary embodiment, there is provided a transmitting apparatus which may include: a zero padder configured to pad at least one zero bit to input bits; an encoder configured to generate an LDPC codeword by performing LDPC encoding with respect to the bits to which the at least one zero bit is padded; a parity interleaver configured to interleave LDPC parity bits constituting the LDPC codeword; and a puncturer configured to puncture at least a part of the interleaved LDPC parity bits based on a pre-set puncturing pattern.

The encoder may generate the LDPC codeword formed of 16200 bits by performing the LDPC encoding at a code rate of 7/15.

The encoder may perform the LDPC encoding based on a parity check matrix formed of an information word sub matrix and a parity sub matrix, and the information word sub matrix may be formed of 21 column groups each including 360 columns and a location of a value 1 in 0^{th} column of each of the column groups may be defined by Table 4 presented below.

The puncturer may determine at least one parity bit group to be punctured from among a plurality of parity bit groups constituting the interleaved LDPC parity bits based on the pre-set puncturing pattern, and may puncture at least a part of the LDPC parity bits included in the determined parity bit group.

The puncturer may puncture at least a part of the interleaved LDPC parity bits based on a puncturing pattern which differs according to a modulation scheme.

The pre-set puncturing pattern may be defined as in Table 5 presented below when a modulation scheme is BPSK or QPSK.

The pre-set puncturing pattern may be defined as in Table 6 presented below when a modulation scheme is BPSK or QPSK.

The pre-set puncturing pattern may be defined as in Table 7 presented below when a modulation scheme is 16-QAM.

The pre-set puncturing pattern may be defined as in Table 8 presented below when a modulation scheme is 16-QAM.

The pre-set puncturing pattern may be defined as in Table 9 presented below when a modulation scheme is 64-QAM.

The pre-set puncturing pattern may be defined as in Table 10 presented below when a modulation scheme is 64-QAM.

The pre-set puncturing pattern may be defined as in Table 11 presented below when a modulation scheme is 256-QAM.

The pre-set puncturing pattern is defined as in Table 12 presented below when a modulation scheme is 256-QAM.

According to an aspect of another exemplary embodiment, there is provided a method for puncturing of a transmitting apparatus which may include: padding at least one zero bit to input bits; generating an LDPC codeword by performing LDPC encoding with respect to the bits to which the at least one zero bit is padded; interleaving LDPC parity bits constituting the LDPC codeword; and puncturing at least a part of the interleaved LDPC parity bits based on a pre-set puncturing pattern.

The generating the LDPC codeword may include generating an LDPC codeword formed of 16200 bits by performing the LDPC encoding at a code rate of 7/15.

The generating the LDPC codeword may include performing the LDPC encoding based on a parity check matrix formed of an information word sub matrix and a parity sub matrix, and the information word sub matrix may be formed of 21 column groups each including 360 columns and a location of a value 1 in 0^{th} column of each of the column groups may be defined by table 4 presented below.

The puncturing may include determining at least one parity bit group to be punctured from among a plurality of parity bit groups constituting the interleaved LDPC parity bits based on the pre-set puncturing pattern, and puncturing at least a part of the interleaved LDPC parity bits included in the determined parity bit group.

The puncturing may include puncturing at least a part of the interleaved LDPC parity bits based on a puncturing pattern which differs according to a modulation scheme.

The pre-set puncturing pattern may be defined as in Table 5 presented below when a modulation scheme is BPSK or QPSK.

The pre-set puncturing pattern may be defined as in Table 6 presented below when a modulation scheme is BPSK or QPSK.

The pre-set puncturing pattern may be defined as in Table 7 presented below when a modulation scheme is 16-QAM.

The pre-set puncturing pattern may be defined as in Table 8 presented below when a modulation scheme is 16-QAM.

The pre-set puncturing pattern may be defined as in Table 9 presented below when a modulation scheme is 64-QAM.

The pre-set puncturing pattern may be defined as in Table 10 presented below when a modulation scheme is 64-QAM.

The pre-set puncturing pattern may be defined as in Table 11 presented below when a modulation scheme is 256-QAM.

The pre-set puncturing pattern is defined as in Table 12 presented below when a modulation scheme is 256-QAM.

According to various exemplary embodiments as described above, the transmitting apparatus efficiently segments and encodes an L1 signaling, and thus, decoding performance can be improved at a receiving apparatus.

### BRIEF DESCRIPTION OF THE DRAWINGS

The above and/or other aspects will be more apparent by describing in detail exemplary embodiments, with reference to the accompanying drawings, in which:

FIG. 1 is a view to illustrate a frame structure used in a related-art broadcasting/communication system;

FIGS. 2 and 3 are block diagrams to illustrate a configuration of a transmitting apparatus according to an exemplary embodiment;

FIG. 4 is a view to illustrate a configuration of a parity check matrix used in LDPC encoding according to an exemplary embodiment;

FIG. 5 is a view to illustrate a method for dividing LDPC parity bits into a plurality of groups according to an exemplary embodiment;

FIGS. 6A and 6B are views to illustrate a puncturing pattern according to an exemplary embodiment;

FIGS. 7 and 8 are block diagrams to illustrate a detailed configuration of a transmitting apparatus according to an exemplary embodiment;

FIGS. 9A and 9B are block diagrams to illustrate a configuration of a receiving apparatus according to an exemplary embodiment;

FIGS. 10 and 11 are block diagrams to illustrate a detailed configuration of a receiving apparatus according to an exemplary embodiment; and

FIG. 12 is a flowchart to illustrate a puncturing method of a transmitting apparatus according to an exemplary embodiment.

### DETAILED DESCRIPTION OF THE EXEMPLARY EMBODIMENTS

Hereinafter, exemplary embodiments will be described in greater detail with reference to the accompanying drawings.

In the following description, same reference numerals are used for the same elements when they are depicted in different drawings. The matters defined in the description, such as detailed construction and elements, are provided to assist in a comprehensive understanding of exemplary embodiments. Thus, it is apparent that exemplary embodiments can be carried out without those specifically defined matters. Also, functions or elements known in the related art are not described in detail since they would obscure the exemplary embodiments with unnecessary detail. Many of the terms used in the exemplary embodiments may correspond to those used in the digital video broadcasting the second generation European terrestrial (DVB-T2) or the Advanced Television System Committee (ATSC) 3.0 standard.

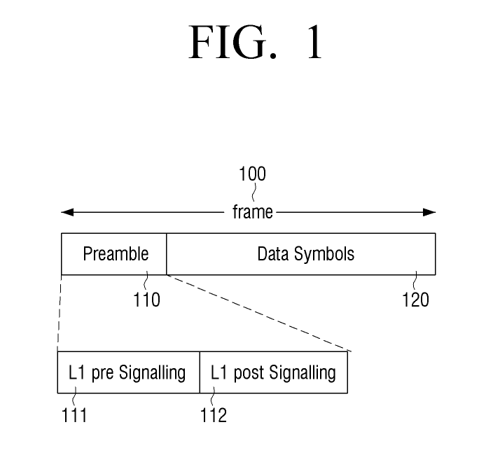

FIG. 1 is a view to illustrate a frame structure used in a related-art broadcasting/communication system. Referring to FIG. 1, a frame 100 includes a preamble 110 and a data symbol 120.

The preamble 110 carries an L1 signaling which includes an L1-pre signaling 111 (that is, L1-pre signaling information) and an L1-post signaling 112 (that is, L1 post signaling information) as shown in FIG. 1.

Herein, the L1-pre signaling 111 includes information that a receiving apparatus (not shown) requires to receive and access the L1-post signaling 112.

The L1-post signaling 112 includes L1 configurable information, L1 dynamic information, Cyclic Redundancy Checking (CRC), L1 padding, etc., and includes a parameter that the receiving apparatus requires to access a Physical Layer Pipe (PLP). Accordingly, the L1-post signaling 112 may have a length which is variable according to the number of PLPs, that is, may be formed of a variable number of bits.

The data symbol 120 carries real broadcast data and may be formed of one or more PLPs. In this case, a different signal processing may independently be performed for each PLP. For example, a different modulation scheme and a different code rate may be used for each PLP.

As described above, a transmitting side in the related-art broadcasting/communication system transmits broadcast data with the frame structure shown in FIG. 1, and a receiving side may acquires information on a scheme in which data is transmitted through an L1 signaling, a frame length, etc., and may receive the broadcast data through the PLPs.

Hereinafter, a method for processing an L1-post signaling with a variable length according to an exemplary embodiment will be explained in detail. Hereinafter, a length of a codeword, information word bits, parity bits, and an L1 signaling refers to the number of bits included in each of them.

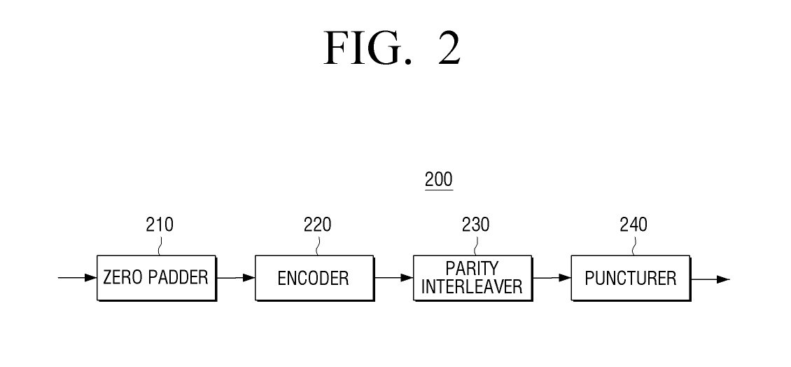

FIG. 2 is a block diagram to illustrate a configuration of a transmitting apparatus according to an exemplary embodiment. Referring to FIG. 2, the transmitting apparatus 200 includes a zero padder 210, an encoder 220, a parity interleaver 230, and a puncturer 240.

The zero padder 210 pads (or inserts) at least one zero bit (or a zero value padding bit) to input bits. Here, the bit to be padded may not be limited to a value 0, and instead, have a different value to achieve the same objective to use the zero bit as described below.

The input bits may be a plurality of segmented L1-post signalings. Specifically, an L1-post signaling may be segmented into the plurality of segmented L1-post signalings so that each segmented L1-post signaling has a smaller number of bits than a predetermined number, and thus, the plurality of segmented L1-post signalings may form bit strings to be input to the zero padder 210. Accordingly, the zero padder 210 may pad at least one zero bit to a bit string, that is, a segmented L1-post signaling.

The reason of padding zero bits by the zero padder 210 is as shown below.

Specifically, a Bose, Chaudhuri, Hocquenghem (BCH) encoder 221 generates a BCH codeword by BCH encoding, and outputs a BCH codeword to an LDPC encoder 222. The LDPC encoder 222 may LDPC-encode the BCH codeword into information word bits. In this case, since the LDPC encoding performed by the LDPC encoder 222 requires information word bits of a certain length according to a code rate, the BCH encoder 221 should generate the BCH codeword having the certain length.

To generate the BCH codeword having the certain length, the BCH encoder 221 should perform BCH encoding with respect to a certain number of bits. Accordingly, the zero padder 210 may pad at least one zero bit into each of the segmented L1-post signalings so that the segmented L1-post signaling has a length of the information word bits required in the BCH encoding.

Thus, the zero padder 210 outputs bits padded with the at least one zero bit into the encoder 220, the bits padded with the at least one zero bit are input bits of the encoder 220. For example, when bits input to the zero padder 210 are formed of K_{sig} bits and the number of bits of the information word bits of the BCH encoding is K_{bch}, and when K_{bch}>K_{sig}, the zero padder 210 may pad K_{bch}−K_{sig} zero bits, and accordingly, the input bits of the encoder 220 may be M=(m₀, m₁, . . . , m_{K}_{_{bch}}₋₁).

Information on the number of zero bits to be padded and padding locations of the zero bits may be pre-stored. In addition, the zero padder 210 may determine this information through an operation according to a pre-defined rule.

In this case, the number of zero bits to be padded and the padding locations of the zero bits may vary according to a structure of a parity check matrix used in the LDPC encoding, a modulation scheme regarding information word bits, and a ratio between the number of LDPC parity bits to be punctured by the puncturer 240 and the number of zero bits to be padded by the zero padder 210.

The information word bits padded with the at least one zero bit are encoded by the encoder 220. After this encoding, the at least one zero bit padded may be removed by the puncturer 240. Removing the zero bits which have been padded after encoding is referred to as “shortening”.

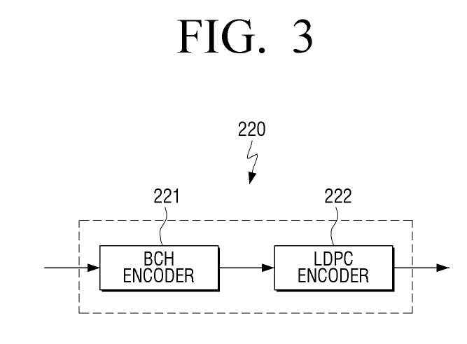

The encoder 220 performs BCH encoding and LDPC encoding with respect to the bits padded with the at least one zero bit. For this encoding, the encoder 220 may include the BCH encoder 221 and the LDPC encoder 222 as shown in FIG. 3.

The BCH encoder 221 performs BCH encoding with respect to each of the bits padded with the at least one zero bit, to generate a plurality of BCH codewords (or BCH-encoded bits). Then, the plurality of BCH codewords are output to the LDPC encoder 222.

Since a BCH code is a systematic code, an information word may be included in a BCH codeword generated by the BCH encoding. That is, since the BCH encoder 221 BCH-encodes the input bits into the information word bits, the BCH codeword includes the input bits which are the information word as it is, and may have BCH parity bits added thereto.

Here, the bits input to the BCH encoder 221 are padded with at least one zero bit, and the number of bits constituting the input bits may be equal to the number of information word bits of a BCH codeword (e.g., K_{bch}).

The LDPC encoder 222 generates an LDPC codeword (or LDPC-encoded bits) by performing LDPC encoding with respect to each of the BCH codewords. In addition, the LDPC encoder 222 outputs the plurality of LDPC codewords generated by the LDPC encoding to the parity interleaver 230.

Since an LDPC code is a systematic code, an information word may be included in an LDPC codeword generated by the LDPC encoding. That is, since the LDPC encoder 222 LDPC-encodes the input bits into the information word bits, the LDPC codeword includes the input bits which are the information word as it is, and may have LDPC parity bits added thereto.

Here, the bits input to the LDPC encoder 222 may be the BCH codeword bits. In this case, since the BCH encoder 221 generates BCH codeword bits as many as the number of information word bits which can be encoded by the LDPC encoder 222 according to a code rate, the number of bits constituting the input bits of the LDPC encoder 222 may be equal to the number of bits of the information word bits of an LDPC codeword (e.g., K_{ldpc}).

For example, the BCH encoder 221 may generate (K_{ldpc}−K_{bch}) number of BCH parity bits by performing BCH encoding with respect to the input bits M=(m₀, m₁, . . . , m_{K}_{_{bch}}₋₁), and may output a BCH codeword I=(i₀, i₁, . . . , i_{K}_{_{ldpc}}₋₁) to the LDPC encoder 220. Here, the BCH codeword may be formed of K_{ldpc} bits.

In addition, the LDPC encoder 221 may generate (N_{ldpc}−K_{ldpc}) number of LDPC parity bits by performing LDPC encoding with respect to the BCH codeword I=(i₀, i₁, . . . , i_{K}_{_{ldpc}}₋₁), and may generate an LDPC codeword C=(c₀, c₁, . . . , c_{N}_{_{ldpc}}₋₁). Here, the LDPC codeword may be formed of N_{ldpc} bits.

In the above-described example, the bits output from the zero padder 210 are input to the BCH encoder 221 and BCH-encoded. However, this is merely an example. The BCH encoder 221 may be omitted in some cases. In this case, the zero padder 210 may pad at least one zero bit to the input bits so that the input bits have a length of the information word bits required by the LDPC encoder 222 according to a code rate, and may output the bits padded with the at least one zero bit to the LDPC encoder 222.

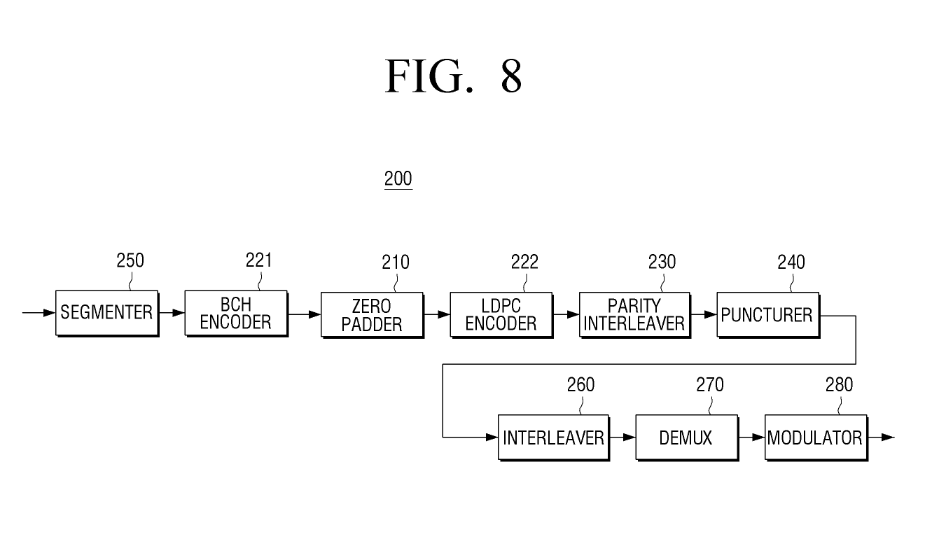

In addition, in the above-described example, the BCH encoder 221 is placed after the zero padder 210. However, this is merely an example. The zero padder 210 may be placed between the BCH encoder 221 and the LDPC encoder 222 according to another exemplary embodiment. This will be explained below with reference to FIG. 8.

The process of performing LDPC encoding is a process of generating an LDPC codeword satisfying H·c^{T}=0. Here, H is a parity check matrix and c is an LDPC codeword. Therefore, the LDPC encoder 222 may generate an LDPC codeword such that a multiplication of the parity check matrix by the LDPC codeword yields 0.

In addition, the LDPC encoder 222 may generate an LDPC codeword having various lengths by performing LDPC encoding according to various code rates. For example, the LDPC encoder 222 may generate an LDPC codeword formed of 16200 bits by performing LDPC encoding at a code rate of 7/15.

However, this is merely exemplary, and the LDPC encoder 222 may perform LDPC encoding according to various code rates such as 3/15, 4/15, 5/15, 6/15, 8/15, 9/15, 10/15, 11/15, 12/15, and 13/15, and may generate a codeword having 64800 bits.

In this case, the LDPC encoder 222 may perform LDPC encoding based on a parity check matrix having a different structure according a code rate and a length of the LDPC codeword. Hereinbelow, a parity check matrix used in LDPC encoding will be explained in detail.

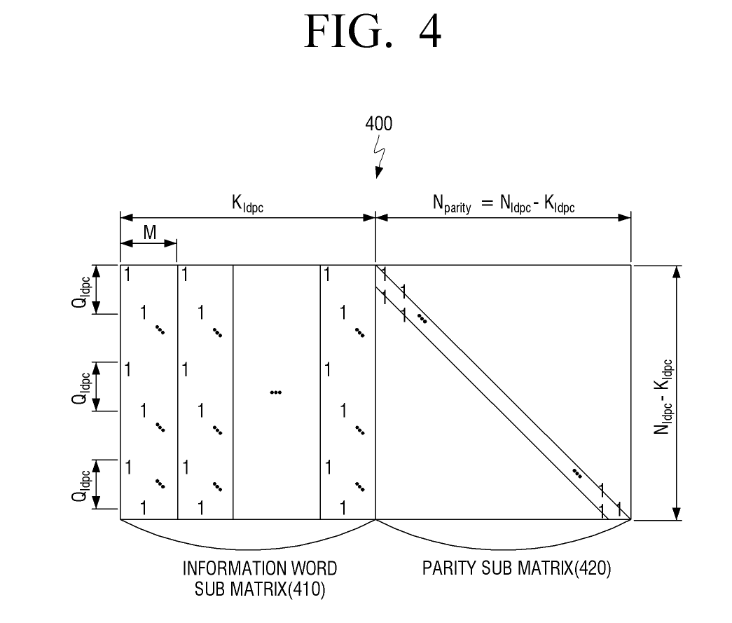

FIG. 4 is a view to illustrate a configuration of a parity check matrix used in LDPC encoding according to an exemplary embodiment.

Referring to FIG. 4, the parity check matrix 400 is formed of an information word sub matrix 410 corresponding to an information word, and a parity sub matrix 420 corresponding to a parity.

The information word sub matrix 410 includes K_{ldpc} number of columns and the parity sub matrix 420 includes N_{parity} (=N_{ldpc}−K_{ldpc}) number of columns. The number of rows of the parity check matrix 400 is identical to the number of columns of the parity sub matrix 420, N_{parity}=N_{ldpc}−K_{ldpc}.

In addition, in the parity check matrix 400, N_{ldpc} is a length of an LDPC codeword, K_{ldpc} is a length of an information word, and N_{parity}=N_{ldpc}−K_{ldpc} is a length of a parity.

Hereinafter, the configurations of the information word sub matrix 410 and the parity sub matrix 420 will be explained in detail. In the information word sub matrix 410 and the parity sub matrix 420, elements other than elements with a value 1 have a value 0.

The information word sub matrix 410 includes K_{ldpc} number of columns (that is, 0^{th} column to (K_{ldpc}−1)^{th} column), and follows the following rules:

First, M number of columns from among K_{ldpc} number of columns of the information word sub matrix 410 belong to a same group, and K_{ldpc} number of columns are divided into K_{ldpc}/M number of column groups. The columns belonging to a same column group are cyclic-shifted from one another by Q_{ldpc}.

Here, M is an interval at which a pattern of columns is repeated in the information word sub matrix 410 (e.g., M=360), and Q_{ldpc} is a size by which each column is cyclic-shifted in the information word sub matrix 410. M and Q_{ldpc} are integers and are determined to satisfy Q_{ldpc}=(N_{ldpc}−K_{ldpc})/M. In this case, K_{ldpc}/M is also an integer. M and Q_{ldpc} may have variable values according to a length of an LDPC codeword and a code rate.

For example, when M=360 and the length N_{ldpc} of the an LDPC codeword is 64800, Q_{ldpc} is defined as shown in Table 1 presented below, and, when M=360 and the length N_{ldpc} of the LDPC codeword is 16200, Q_{ldpc} may be defined as shown in Table 2 presented below:

TABLE 1

| Code Rate | N_{ldpc} | M | Q_{ldpc} |
|---|---|---|---|
| 5/15 | 64800 | 360 | 120 |
| 6/15 | 64800 | 360 | 108 |
| 7/15 | 64800 | 360 | 96 |
| 8/15 | 64800 | 360 | 84 |
| 9/15 | 64800 | 360 | 72 |
| 10/15 | 64800 | 360 | 60 |
| 11/15 | 64800 | 360 | 48 |
| 12/15 | 64800 | 360 | 36 |
| 13/15 | 64800 | 360 | 24 |

TABLE 2

| Code Rate | N_{ldpc} | M | Q_{ldpc} |
|---|---|---|---|
| 5/15 | 16200 | 360 | 30 |
| 6/15 | 16200 | 360 | 27 |
| 7/15 | 16200 | 360 | 24 |
| 8/15 | 16200 | 360 | 21 |
| 9/15 | 16200 | 360 | 18 |
| 10/15 | 16200 | 360 | 15 |
| 11/15 | 16200 | 360 | 12 |
| 12/15 | 16200 | 360 | 9 |
| 13/15 | 16200 | 360 | 6 |

Second, when the degree of 0^{th} column of i^{th} column group (I=0, 1, . . . , K_{ldpc}/M−1) is Dᵢ (here, the degree is the number of is existing in a column and all columns belonging to a same column group have a same degree), and a position of each row where 1 exists is R_{i,0}⁽⁰⁾, R_{i,0}⁽¹⁾, . . . , R_{i,0}^{(D}^{ᵢ}⁻¹⁾, an index R_{i,j}^{(k)} of a row where weight−1 is located in j^{th} column in the i^{th} column group (that is, an index of a row where k^{th} 1 is located in the j^{th} column in the i^{th} column group) is determined by following Equation 1:

R_{i,j}^{(k)}=R_{i,(j-1)}^{(k)}+Q_{ldpc} mod(N_{ldpc}−K_{ldpc}) (1),

where k=0, 1, 2, . . . , Dᵢ−1, i=0, 1, . . . , K_{ldpc}/M−1, and j=1, 2, . . . , M−1.

Equation 1 can be expressed as following Equation 2:

R_{i,j}^{(k)}=R_{i,0}^{(k)}+(j mod M)×Q_{ldpc}/mod(N_{ldpc}−K_{ldpc}) (2),

where k=0, 1, 2, . . . , Dᵢ−1, i=0, 1, . . . , K_{ldpc}/M−1, and j=1, 2, . . . , M−1.

In the above equations, R_{i,j}^{(k)} is an index of a row where k^{th} weight−1 is located in the j^{th} column in the i^{th} column group, N_{ldpc} is a length of an LDPC codeword, K_{ldpc} is a length of an information word, Dᵢ is a degree of columns belonging to the i^{th} column group, M is the number of columns belonging to a single column group, and Q_{ldpc} is a size by which each column is cyclic-shifted.

Referring to Equation 2, when only R_{i,0}^{(k)} is known, the index R_{i,j}^{(k)} of the row where the k^{th} weight−1 is located in the i^{th} column group can be known. Therefore, when an index value of a row where the k^{th} weight−1 is located in the first column of each column group is stored, a position of column and row where weight−1 is located in the information word sub matrix 410 having the configuration of FIG. 4 can be known.

According to the above-described rules, all of the columns belonging to the i^{th} column group have the same degree Dᵢ. Accordingly, the LDPC code which stores information on the parity check matrix according to the above-described rules may be briefly expressed as follows.

For example, when N_{ldpc} is 30, K_{ldpc} is 15, and Q_{ldpc} is 3, position information about a row where weight−1 is located in the 0^{th} column of the three column groups may be expressed by a sequence as shown in Equation 3, and may be referred to as ‘weight−1 position sequence’.

R_{1,0}⁽¹⁾=0,R_{1,0}⁽²⁾=2,R_{1,0}⁽³⁾=8,R_{1,0}⁽⁴⁾=10,

R_{2,0}⁽¹⁾=0,R_{2,0}⁽²⁾=9,R_{2,0}⁽³⁾=13,

R_{3,0}⁽¹⁾=0,R_{3,0}⁽²⁾=14.

where R_{i,j}^{(k)} is an index of a row where k^{th} weight−1 is located in the j^{th} column in the i^{th} column group.

The weight−1 position sequence like Equation 3 which expresses an index of a row where 1 is located in the 0^{th} column of each column group may be briefly expressed as in Table 3 presented below:

TABLE 3

1 2 8 10
0 9 13
0 14

Table 3 shows positions of elements having weight−1, that is, a value 1, in the parity check matrix, and the i^{th} weight−1 position sequence is expressed by indexes of rows where weight−1 is located in the 0^{th} column belonging to the i^{th} column group.

The information word sub matrix according to an exemplary embodiment may be defined as in Table 4 presented below, based on the above descriptions. That is, the information word sub matrix is formed of 21 column groups each including 360 columns, and a position of a value 1 in the 0^{th} column of each of the column groups may be defined as in Table 4 presented below. In this case, the length N_{ldpc} of the LDPC codeword is 16200, the code rate is 7/15, and M is 360.

TABLE 4

| | Index of row where 1 is |
|---|---|
| i | located in the 0th column of ith column group |
| 0 | 432 655 893 942 1285 1427 1738 2199 2441 2565 2932 3201 4144 |
| | 4419 4678 4963 5423 5922 6433 6564 6656 7478 7514 7892 |
| 1 | 220 453 690 826 1116 1425 1488 1901 3119 3182 3568 3800 3953 |
| | 4071 4782 5038 5555 6836 6871 7131 7609 7850 8317 8443 |
| 2 | 300 454 497 930 1757 2145 2314 2372 2467 2819 3191 3256 3699 |
| | 3984 4538 4965 5461 5742 5912 6135 6649 7636 8078 8455 |
| 3 | 24 65 565 609 990 1319 1394 1465 1918 1976 2463 2987 3330 |
| | 3677 4195 4240 4947 5372 6453 6950 7066 8412 8500 8599 |
| 4 | 1373 4668 5324 7777 |
| 5 | 189 3930 5766 6877 |
| 6 | 3 2961 4207 5747 |
| 7 | 1108 4768 6743 7106 |
| 8 | 1282 2274 2750 6204 |
| 9 | 2279 2587 2737 6344 |
| 10 | 2889 3164 7275 8040 |
| 11 | 133 2734 5081 8386 |
| 12 | 437 3203 7121 |
| 13 | 4280 7128 8490 |
| 14 | 619 4563 6206 |
| 15 | 2799 6814 6991 |
| 16 | 244 4212 5925 |
| 17 | 1719 7657 8554 |
| 18 | 53 1895 6685 |
| 19 | 584 5420 6856 |
| 20 | 2958 5834 8103 |

Table 4 shows indexes of rows where 1 is located in the 0^{th} column of the i^{th} column group of the information word sub matrix 410 of the parity check matrix 400, and the position of 1 in the information word sub matrix 410 may be defined based on Table 4.

Specifically, the position of the row where 1 exists in the 0^{th} column of each column group may be defined based on Table 4. For example, in a case of the 0^{th} column of the 0^{th} column group, 1 may exist in the 432^{nd} row, 655^{th} row, 893^{rd} row, . . . .

In addition, by shifting the row where 1 is located in the 0^{th} column of each column group by Q_{ldpc} a row where 1 is located in another column of the corresponding column group may be defined.

Specifically, since Q_{ldpc}=(16200−7560)/360=24 and the indexes of the rows where 1 is located in the 0^{th} column of the 0^{th} column group are 432, 655, 893, . . . , indexes of rows where 1 is located in the 1^{st} column of the 0^{th} column group are 456 (=432+24), 679 (=655+24), 917 (=893+24), . . . , and indexes of rows where 1 is located in the 2^{nd} column of the 0^{th} column group are 480 (=456+24), 703 (=679+24), 941 (=917+24) . . . .

The parity sub matrix 420 includes N_{ldpc}−K_{ldpc} number of columns (that is, K_{ldpc}^{th} column to (N_{ldpc}−1)^{th} column), and has a dual diagonal configuration. Accordingly, the degree of columns except for the last column (that is, (N_{ldpc}−1)^{th} column) from among the columns included in the parity sub matrix 420 is 2, and the degree of the last column (that is, (N_{ldpc}−1)^{th} column) is 1.

As a result, when the length N_{ldpc} of the LDPC codeword is 16200, the length K_{ldpc} of the information word is 7560, the code rate is 7/15, and M is 360, the indexes of the rows where 1 is located in the 0^{th} column of the 1 column group of the information word sub matrix 410 are defined as in Table 4, and the parity sub matrix 420 may have a dual diagonal configuration. Information on the parity check matrix 400 described above may be pre-stored in the transmitting apparatus 200.

Referring to FIG. 2, the parity interleaver 230 interleaves LDPC parity bits constituting an LDPC codeword. That is, the parity interleaver 230 may interleave the LDPC parity bits included in each of the LDPC codewords, and may output a plurality of parity-interleaved LDPC codewords to the puncturer 240.

Specifically, the parity interleaver 230 may interleave only LDPC parity bits of LDPC codewords C=(c₀, c₁, . . . , c_{N}_{_{ldpc}}₋₁) output from the LDPC encoder 220 based on Equation 4 presented below, and may output the parity-interleaved LDPC codewords U=(u₀, u₁, . . . , u_{N}_{_{ldpc}}₋₁) to the puncturer 240.

uᵢ=cᵢfor0≦i<K_{ldpc}

u_{K}_{_{ldpc}}_{+M·t+s}=C_{K}_{_{ldpc}}_{+Q}_{_{ldpc}}_{·s+t}for0≦s<M,0≦t<Q_{ldpc} (4),

where M is an interval at which a pattern of columns is repeated in the information word sub matrix 410, that is, the number of columns included in a column group, and Q_{ldpc} is a size by which each column is cyclic-shifted in the information word sub matrix 410. In addition, K_{ldpc} is the number of bits of information word bits constituting an LDPC codeword.

For example, when the length N_{ldpc} of an LDPC codeword is 16200, the code rate is 7/15, and M is 360, Q_{ldpc} may be 24 and K_{ldpc} may be 7560.

The LDPC codeword which is parity-interleaved in the above-described method may be formed of a certain number of continuous bits which have the same property, and they may have the same cycle distribution and the same degree.

For example, the parity-interleaved LDPC codeword may have a same property in the unit of M number of continuous bits. Here, M is the number of columns included in a same column group in the parity check matrix 400, and M=360, for example. That is, since M number of columns of the parity check matrix 400 have a same degree, M number of continuous bits have a same degree of column in the parity check matrix 400 and have a substantially large cycle property, and thus these bits have a low decoding correlation.

That is, in the case of the parity check matrix 400 having the configuration shown in FIG. 4, since the information word sub matrix 410 has a same property in a unit of a column group including M number of columns, the information word bits generated based on the parity check matrix 400 may be formed of M number of continuous bits having a same codeword property. When the LDPC parity bits are interleaved based on Equation 4, the LDPC parity bits may be formed of M number of continuous bits having a same codeword property, considering that M number of continuous bits having a same property can be arranged adjacent to one another.

As described above, bits constituting an LDPC codeword may have a same property in a unit of M number of continuous bits.

The parity interleaver 230 may be omitted in some cases. Specifically, the parity check matrix 400 may be row-permutated based on Equation 5 presented below, and may be column-permutated based on Equation 6 presented below, and the parity interleaver 230 may be omitted when the LDPC encoder 222 performs LDPC encoding based on a parity check matrix generated by permutating. The row-permutating refers to changing the order of rows of the parity check matrix 400, and the column-permutating refers to changing the order of columns of the parity check matrix 400:

Q_{ldpc}·i+j [symbol] M·j+i(0≦i<M,0≦j<Q_{ldpc}) (5)

K_{ldpc}+Q_{ldpc}·k+l [symbol] K_{ldpc}+M·l+k(0≦k<M,0≦l<Q_{ldpc}) (6)

In the above Equations, K_{ldpc} may be 7560, M may be 360, and Q_{ldpc} may be 24.

The method for permutating based on Equation 5 and Equation 6 is as follows. Since the column-permutating applies the same principle as the row-permutating except that the column-permutating is applied only to the parity sub matrix 420, the row-permutating will be explained by the way of an example.

In the case of the row-permutating, regarding the X^{th} row, i and j satisfying X=Q_{ldpc}×i+j are calculated, and the X^{th} row is permutated by assigning the calculated i and j to M×j+i. For example, regarding the 50^{th} row, i and j satisfying 50=24×i+j are 2 and 2, respectively. Therefore, the 50^{th} row is permutated to 360×2+2=722^{th} row.

When the parity check matrix 400 shown in FIG. 4 is permutated in the above-described method, the parity check matrix 400 is divided into a plurality of partial blocks and each of the partial blocks may have a configuration corresponding to a M×M quasi-cyclic matrix. Accordingly, LDPC parity bits generated based on the permutated parity check matrix may have the same property in a unit of M number of continuous bits. Accordingly, when an LDPC codeword is generated based on a parity check matrix having such a configuration, the parity interleaver 230 may be omitted.

The puncturer 240 may puncture at least some of LDPC parity bits constituting an LDPC codeword. That is, the puncturer 240 may puncture at least some LDPC parity bits of each of a plurality of LDPC codewords. The puncturing refers to removing some of the parity bits not to transmit them.

Specifically, the puncturer 240 may puncture at least a part of interleaved LDPC parity bits based on a pre-set puncturing pattern. The pre-set puncturing pattern indicates an order of parity bit groups to be punctured, and the order of the parity bit groups to be punctured may be different according to a modulation method.

Hereinafter, a method for puncturing LDPC parity bits according to a pre-set puncturing pattern will be explained in detail. Since a plurality of LDPC codewords can be punctured by a same method, a method for puncturing a single LDPC codeword will be explained for convenience of explanation. In addition, bits input to the zero padder 210 are indicated by a segmented L1post-signaling.

The puncturer 240 divides LDPC parity bits into a plurality of parity bit groups based on Equation 7 presented below:

$${P}_{j} = \{ {u}_{k} \vert j = ⌊ \frac{k - {K}_{ldpc}}{360} ⌋ , {K}_{ldpc} \leq k < {N}_{ldpc} \} for 0 \leq j < {Q}_{ldpc} , \qquad ( 7 )$$

where Pⱼ is j^{th} parity bit group of the LDPC parity bits, and uₖ is bits input to the puncturer 240 (that is, bits constituting the LDPC codeword). └x┘ is the greatest integer less than x, and └1.2┘=1, for example.

K_{ldpc} is the number of information word bits of the LDPC codeword, N_{ldpc} is the number of bits of the LDPC codeword, and Q_{ldpc} is a size by which each column is cyclic-shifted in the information word sub matrix 410. For example, K_{ldpc} may be 7560, N_{ldpc} may be 16200, and Q_{ldpc} may be 24.

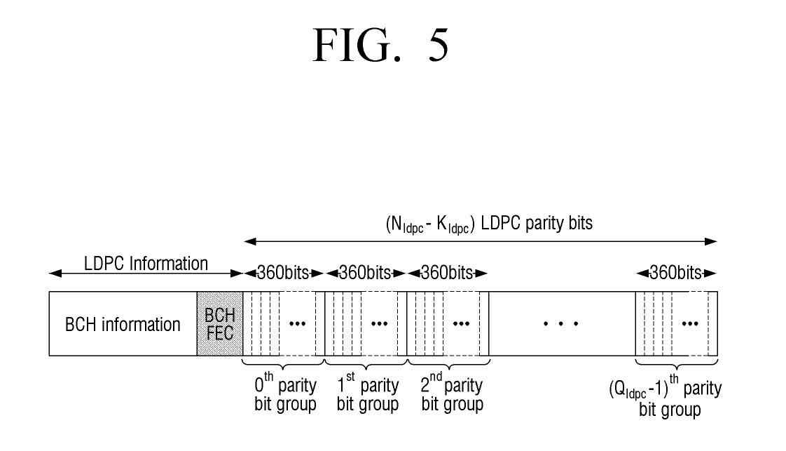

That is, the puncturer 240 may divide the LDPC parity bits (u_{K}_{_{ldpc}}, u_{K}_{_{ldpc}}₊₁, . . . u_{N}_{_{ldpc}}₋₁) of the parity-interleaved LDPC codeword (u₀, u₁, . . . , u_{N}_{_{ldpc}}₋₁) into Q_{ldpc} number of parity bit groups, based on FIG. 5 and Equation 7. Accordingly, each of the parity bit groups may consist of 360 (=(N_{ldpc}−K_{ldpc}) Q_{ldpc}=M) bits.

Equation 7 can be expressed by Equation 8 or Equation 9 presented below:

Pⱼ={uₖ|360×j≦k−K_{ldpc}<360×(j+1),K_{ldpc}≦k<N_{ldpc}}for0≦j<Q_{lpdc} Equation 8

Pⱼ={uₖ|K_{lpdc}+360×j≦k<K_{ldpc}<360×(j+1),K_{ldpc}≦k<N_{ldpc}}for0≦j<Q_{lpdc} Equation 9

As described above, the puncturer 240 may divide the LDPC parity bits into the plurality of parity bit groups.

The puncturer 240 may calculate the number of LDPC parity bit groups to be punctured.

To do this, the puncturer 240 may calculate the number of LDPC parity bits to be temporarily punctured, N_{punc}_{_{—}}ₜₑₘₚ, based on Equation 10 presented below:

N_{punc}_{_{—}}ₜₑₘₚ=└A×(N_{L1post}_{_{—}}_{segmentation}−K_{sig})┘−B (10)

where └x┘ is the greatest integer less than x, and └1.2┘=1, for example.

In addition, K_{sig} is the number of information word bits input to the zero padder 210, that is, the number of bits of a segmented L1-post signaling, and N_{L1post}_{_{—}}_{segmentation} is a reference value for segmenting the L1-post signaling and indicates the maximum number of bits that a segmented L1 signaling can have.

That is, when the number of bits of the L1-post signaling is greater than a certain value (e.g., N_{L1post}_{_{—}}_{segmentation}), the L1-post signaling may be segmented and the segmented L1-post signalings may be input to the zero padder 210. In this case, the L1-post signaling may be segmented such that the maximum number of bits of a segmented L1-post signaling is N_{L1post}_{_{—}}_{segmentation}. That is, the L1-post signaling is segmented such that a segmented L1-post signaling does not exceed N_{L1post}_{_{—}}_{segmentation}. Therefore, when the number of bits of a segmented L1 signaling is K_{sig}, K_{sig}≦N_{L1post}_{_{—}}_{segmentation}.

Here, N_{L1post}_{_{—}}_{segmentation} may be less than the number of the information word bits required for BCH encoding, K_{bch}. Accordingly, when K_{bch}−K_{sig} number of zero bits are shortened, N_{L1post}_{_{—}}_{segmentation}−K_{sig} of Equation 10 may be regarded as indicating the number of additionally shortened zero bits.

A and B are correction factors for determining a ratio of the number of bits to be additionally shortened and the number of bits to be punctured, and may satisfy A>0 and B may be determined to be an integer.

In the above-described method, the puncturer 240 can calculate the number of LDPC parity bits to be temporarily punctured.

Then, the puncturer 240, based on the number of LDPC parity bits to be temporarily punctured, may calculate the number of LDPC parity bits which are to be punctured, that is, the number of LDPC parity bits to be finally punctured.

Specifically, the puncturer 240, when a value calculated by subtracting the number of LDPC parity bits to be temporarily punctured from the number of LDPC parity bits is an integer multiple of a modulation order, the number of LDPC parity bits to be temporarily punctured may be determined as the number of LDPC parity bits to be punctured.

The puncturer 240, when a value calculated by subtracting the number of LDPC parity bits to be temporarily punctured from the number of LDPC parity bits is not an integer multiple of the modulation order, may calculate the number of LDPC parity bits to be additionally punctured, and determine a value of adding the calculated additional bit number and the number of LDPC parity bits to be temporarily punctured as the number of LDPC parity bits to be punctured.

For example, when a modulation scheme is 16-QAM, one modulation symbol is formed of four bits. If a value which subtracts the bit number of LDPC parity bits to be temporarily punctured from the LDPC parity bits is not an integer multiple of 4, the puncturer 240 may calculate the number of LDPC parity bits to be additionally punctured which makes the number of the LDPC parity bits remaining after the additional puncturing an integer multiple of 4, and may add the number of LDPC parity bits to be additionally punctured and the number of LDPC parity bits to be temporarily punctured to determine the number of LDPC parity bits to be punctured.

The above described method is merely exemplary, and the number of LDPC parity bits to be punctured may be determined based on other transmission parameters in addition to a modulation scheme. Such transmission parameters include, for example, the number of carriers of an Orthogonal Frequency Division Multiplexing (OFDM) symbol and the number of bits to transmit.

The puncturer 240, based on the number of LDPC parity bits to be punctured, may calculate the number of parity bit groups to be punctured in a group unit, from among a plurality of parity bit groups constituting the LDPC parity bits.

In this case, the puncturer 240 may calculate the number of parity bit groups, N_{punc}_{_{—}}_{group}, which is to be punctured in a group unit, based on Equation 11 below.

$${N}_{punc\_group} = ⌊ \frac{{N}_{punc}}{M} ⌋ for 0 \leq {N}_{punc} < {N}_{ldpc} - {K}_{ldpc} \qquad ( 11 )$$

where N_{punc} is the number of LDPC parity bits to be punctured. M is an interval in which a pattern of a column is repeated at an information word sub matrix (for example, M=360), and M is equal to the number of LDPC parity bits included in each parity bit group. In addition, N_{ldpc} is the length of an LDPC codeword and K_{ldpc} is the length of information word bits. In addition, └x┘ is the greatest integer smaller than x, for example, └1.2┘=1.

Then, the puncturer 240, based on a pre-set puncturing pattern, may perform puncturing the LDPC parity bits by the calculated number. Herein, the puncturing pattern indicates an order of parity bit groups.

Accordingly, the puncturer 240 may determine a parity bit group to be punctured based on a pre-set puncturing pattern from among a plurality of parity bit groups constituting the interleaved LDPC parity bits, and perform puncturing of at least a part of LDPC parity bits included in the determined parity bit group.

Specifically, the puncturer 240, if the number of LDPC parity bits to be punctured is divided by M, may select as many parity bit groups as the number of parity bit groups calculated based on Equation 11, from among a plurality of parity bit groups constituting the LDPC parity bits, and puncture the selected parity bit groups.

However, if the number of LDPC parity bits to be punctured is not divided into M, the puncturer 240 may select, based on a pre-set puncturing pattern, as many parity bit groups as the number of parity bit groups calculated based on Equation 11, from among a plurality of parity bit groups constituting the LDPC parity bits, and puncture the selected parity bit groups.

In this case, the puncturer 240 may additionally select one parity bit group and additionally puncture at least a part of LDPC parity bits from among the LDPC parity bits included in the additionally selected parity bit group.

Specifically, the puncturer 240 may additionally select a parity bit group to be punctured following the finally-selected parity group based on a pre-set puncturing pattern, and may additionally puncture at least a part of LDPC parity bits included in the additionally selected parity bit group. In this case, the number of LDPC parity bits to be additionally punctured may be calculated by subtracting the number of LDPC parity bits to be punctured in a group unit from the number of LDPC parity bits to be punctured.

The puncturing pattern may be differently defined according to a modulation scheme. Accordingly, the puncturer 240 may puncture at least a part of LDPC parity bits based on a different puncturing pattern according to a modulation scheme.

Hereinafter, with reference to Tables 5 to 12, an example of a puncturing pattern according to a modulation scheme will be explained in detail. In addition, πₚ(j) defined in Table 5 to 12 may be determined according to a code rate, a length of an LDPC codeword, a modulation scheme, a ratio of the number of bits to be punctured and the number of bits to be shortened, or the like.

Meanwhile, examples of the puncturing pattern which will be explained below may apply only when an LDPC codeword is generated to have 16200 bits at a code rate of 7/15 based on the parity check matrix shown in FIG. 4. In addition, since M=360, Q_{ldpc} may be 24.

For example, when the length N_{ldpc} of the LDPC codeword is 16200, the code rate is 7/15, A=2 and B=0 in Equation 10, and the modulation scheme is BPSK or QPSK, the puncturing pattern may be defined as in Table 5 or Table 6 presented below:

TABLE 5

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| BPSK/ | 7/15 | 18 | 6 | 11 | 3 | 21 | 0 | 14 | 8 | 16 | 19 | 22 | 2 |
| QPSK | | 10 | 5 | 13 | 23 | 9 | 17 | 4 | 15 | 1 | 20 | 12 | 7 |

TABLE 6

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| BPSK/ | 7/15 | 18 | 6 | 11 | 4 | 0 | 14 | 22 | 9 | 2 | 16 | 20 | 12 |
| QPSK | | 7 | 21 | 17 | 3 | 10 | 1 | 15 | 8 | 19 | 5 | 13 | 23 |

In these tables, πₚ(j) is an index of a parity bit group to be punctured j^{th}.

In another example, when the length N_{ldpc} of the LDPC codeword is 16200, the code rate is 7/15, A=2 and B=0 in Equation 10, and the modulation scheme is 16-Quadrature Amplitude Modulation (QAM), the puncturing pattern may be defined as in Table 7 or Table 8 presented below:

TABLE 7

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 16QAM | 7/15 | 4 | 11 | 20 | 18 | 7 | 15 | 13 | 23 | 1 | 9 | 6 | 17 |
| | | 3 | 12 | 19 | 0 | 22 | 8 | 14 | 2 | 21 | 16 | 10 | 5 |

TABLE 8

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 16QAM | 7/15 | 4 | 11 | 14 | 6 | 18 | 0 | 22 | 9 | 20 | 2 | 12 | 16 |
| | | 7 | 19 | 15 | 1 | 10 | 5 | 21 | 13 | 3 | 17 | 8 | 23 |

In these tables, πₚ(j) is an index of a parity bit group to be punctured j^{th}.

In another example, when the length N_{ldpc} of the LDPC codeword is 16200, the code rate is 7/15, A=2 and B=0 in Equation 10, and the modulation scheme is 16-QAM, the puncturing pattern may be defined as in Table 9 or Table 10 presented below:

TABLE 9

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 64QAM | 7/15 | 11 | 18 | 7 | 0 | 3 | 14 | 21 | 9 | 5 | 23 | 16 | 12 |
| | | 19 | 2 | 8 | 15 | 22 | 10 | 4 | 17 | 1 | 13 | 6 | 20 |

TABLE 10

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 64QAM | 7/15 | 18 | 6 | 0 | 13 | 3 | 9 | 21 | 11 | 16 | 20 | 2 | 8 |
| | | 5 | 14 | 17 | 22 | 10 | 19 | 1 | 7 | 15 | 4 | 12 | 23 |

In these tables, πₚ(j) is an index of a parity bit group to be punctured j^{th}.

In another example, when the length N_{ldpc} of the LDPC codeword is 16200, the code rate is 7/15, A=2 and B=0 in Equation 10, and the modulation scheme is 256-QAM, the puncturing pattern may be defined as in Table 11 or Table 12 presented below:

TABLE 11

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 256QAM | 7/15 | 4 | 16 | 11 | 20 | 7 | 18 | 0 | 22 | 13 | 2 | 9 | 5 |
| | | 19 | 14 | 8 | 1 | 21 | 10 | 17 | 6 | 15 | 3 | 12 | 23 |

TABLE 12

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 256QAM | 7/15 | 4 | 21 | 6 | 11 | 13 | 18 | 0 | 15 | 2 | 9 | 7 | 22 |
| | | 19 | 1 | 17 | 10 | 14 | 20 | 16 | 5 | 8 | 3 | 12 | 23 |

In these tables, πₚ(j) is an index of a parity bit group to be punctured j^{th}.

Such a puncturing pattern may be pre-stored or may be determined by the puncturer 240 through an operation according to a pre-defined rule.

Hereinbelow, a method of puncturing by the puncturer 240 at least a part of LDPC parity bits based on a puncturing pattern will be explained in greater detail.

For convenient explanation, it is assumed that the puncturing pattern is defined as Table 7, and the number of LDPC parity bits to be punctured is 2160 or 1500.

For example, if the number of LDPC parity bits to be punctured is 2160, the number of parity bit groups to be punctured based on Equation 11 may be 6, and the number of LDPC parity bits to be punctured is divided by M.

In this case, the puncturer 240, based on the puncturing pattern as Table 7, may select 6 parity bit groups from among a plurality of parity bit groups constituting the LDPC parity bits, and puncture the selected six parity bit groups.

That is, referring to Table 7, the index of a parity group to be punctured 0^{th} is πₚ(0)=4, and thus, 4^{th} parity group is punctured 0^{th}, that is, punctured first. Accordingly, the puncturer 240, when six parity bit groups are punctured, from among 0^{th} to 23^{rd} parity bit groups constituting the LDPC parity bits, may select 4^{th} parity bit group P₄ (=Pπₚ(0)), 11th parity bit group P₁₁ (=Pπₚ(1)), 20^{th} parity bit group P₂₀ (=Pπₚ(2)), 18^{th} parity bit group P₁₈ (=Pπₚ(3)), 7^{th} parity bit group P₇ (=Pπₚ(4)), and 15^{th} parity bit group P₁₅ (=Pπₚ(5)), and puncture these parity bit groups in the selected order.

As described above, the puncturer 240 may select N_{punc}_{_{—}}_{group} parity bit groups Pπₚ(0), Pπₚ(1), . . . , Pπₚ(N_{punc}_{_{—}}_{group-1}) based on the puncturing pattern, and puncture the selected parity bit groups.

As another example, when the number of LDPC parity bits to be punctured is 1500, the number of parity bit groups to be punctured based on Equation 11 may be 4, and the number of LDPC parity bits to be punctured will not be divided into M.

In this case, the puncturer 240, based on the puncturing pattern as Table 7, may select four parity bit groups from among a plurality of parity bit groups constituting the LDPC parity bits, and puncture the selected four parity bit groups.

That is, referring to Table 7, the index of a parity bit group which is punctured 0^{th} is πₚ(0)=4, and therefore, the fourth parity bit group is punctured 0^{th}, that is, punctured first. Accordingly, the puncturer 240, when four parity bit groups are punctured, may select, from among 0^{th} to 23^{rd} parity bit groups constituting the LDPC parity bits, the fourth parity group P₄ (=Pπₚ(0)), 11^{th} parity bit group P₁₁ (=Pπₚ(1)), 20^{th} parity bit group P₂₀ (=Pπₚ(2)), and 18^{th} parity bit group P₁₈ (=Pπₚ(3)), and puncture these parity bit groups in the selected order.

In addition, the puncturer 240 may select 7^{th} parity bit group P₇ (=Pπₚ(4)) which is a parity bit group to be punctured following 18^{th} parity bit group P₁₈ and additionally puncture a part of LDPC parity bits included in the 7^{th} parity bit group P₇.

In this case, the number of LDPC parity bits to be punctured in the 7^{th} parity bit group is a value obtained by subtracting the number of LDPC parity bits to be punctured in a group unit from the LDPC parity bits to be punctured, and the value may be 1500−(360×4)=60. The puncturer 240 may puncture 60 LDPC parity bits from the front end or the back end of the 7^{th} parity bit group P₇.

As described above, the puncturer 240, based on the puncturing pattern, may select N_{punc}_{_{—}}_{group} number of parity bit groups, Pπₚ(0), Pπₚ(1), . . . , Pπₚ(N_{punc}_{_{—}}_{group-1}), and puncture these selected parity bit groups.

And, the puncturer 240, from among LDPC parity bits included in the parity bit group Pπₚ(N_{punc}_{_{—}}_{group}), may puncture N_{punc}−M×N_{punc}_{_{—}}_{group} number of LDPC parity bits. In this case, the bits to be punctured at the parity bit group Pπₚ(N_{punc}_{_{—}}_{group}) may be N_{punc}−M×N_{punc}_{_{—}}_{group} number of LDPC parity bits which are located at the front end or the back end of Pπₚ(N_{punc}_{_{—}}_{group}).

Meanwhile, the above puncturing method may be described as follows.

The puncturer 240 may puncture at least a part of the interleaved-parity bits. In other words, the puncturer 240 may receive from the parity interleaver 230 the LDPC codeword where the LDPC parity bits are interleaved, and puncture at least a part of the LDPC parity bits constituting the LDPC codeword.

To be specific, the puncturer 240 may group parity bits based on an interval at which a pattern of columns is repeated in the information word sub matrix constituting a parity check matrix, and perform puncturing based on the number of punctured parity bits and the position of the punctured parity bit groups from among the groups of parity bits.

Here, the interval at which a pattern of columns is repeated in the information word sub matrix constituting the parity check matrix indicates the number of columns which belong to the same column group in the information word sub matrix, which may be represented as M as described above in FIG. 4, and the specific example may be M=360.

To do so, the puncturer 240 may group the LDPC parity bits based on the interval at which a pattern of columns is repeated in the information word sub matrix constituting the parity check matrix, and divide the LDPC parity bits into a plurality of parity bit groups.

To be specific, the puncturer 240 may divide the parity bits into a plurality of parity groups so that each parity bit group consists of the number of bits as many as the interval at which a pattern of columns is repeated in the information word sub matrix.

For example, the puncturer 240, based on Equations 7 to 9 shown above, may divide the LDPC parity bit (u_{K}_{_{ldpc}}, u_{K}_{_{ldpc}}₊₁, . . . , u_{N}_{_{ldpc}}₋₁) consisting of N_{ldpc}−K_{ldpc} bits to Q_{ldpc} parity bit groups. In this case, each parity bit group may form a subset of the interleaved LDPC parity bits.

FIG. 5 illustrates that the LDPC parity bits are divided into a plurality of groups according to an exemplary embodiment. As illustrated in FIG. 5, the LDPC parity bits may be divided into the parity bit groups in the number of Q_{ldpc} and each parity bit group may be composed of 360=(N_{ldpc}−K_{ldpc})/Q_{ldpc} bits.

The puncturer 240 may determine the number of parity bits to be punctured. Herein, the number of parity bits to be punctured, N_{punc}, is determined by above mentioned method.

The puncturer 240 may determine the position of the parity bit groups to be punctured based on the pre-defined puncturing pattern and the number of parity bits to be punctured.

Herein, the pre-defined puncturing pattern indicates the order of the parity bit groups to be punctured and for example, the puncturing pattern may be defined as shown in Table 5 to Table 12.

Meanwhile, the puncturer 240 may determine the number of parity bit groups to be punctured based on a value which is obtained by dividing the number of parity bits to be punctured by the interval at which a pattern of columns is repeated in the information word sub matrix, and determine the position of parity bit groups to be punctured according to the determined number of parity groups and the pre-defined puncturing pattern.

To do so, the puncturer 240 may calculate N_{punc}_{_{—}}_{group} based on the Equation 11. Herein, N_{punc}_{_{—}}_{group} indicates the number of parity bit groups which are punctured by group, that is, the number of parity bit groups where all bits in the corresponding parity bit group are punctured.

If the number of parity bits to be punctured is exactly divided by the interval at which a pattern of columns is repeated without any remainder, the puncturer 240 may determine the quotient as the number of parity bit groups to be punctured, and may puncture the parity bit groups at the determined position by group according to the pre-defined puncturing pattern.

In other words, if the number of parity bits to be punctured is exactly divided by the interval at which a pattern of columns is repeated without any remainder, the puncturer 240 may determine that N_{punc}_{_{—}}_{group} is the number of parity bit groups to be puctured, and may determine πₚ(0)^{th} group (=Pπₚ(0)), πₚ(1)^{th} group (=Pπₚ(1)), . . . , πₚ(N_{punc}_{_{—}}_{group}−1)^{th} group (=Pπₚ(N_{punc}_{_{—}}_{group}−1) as the parity bit groups to be punctured based on the pre-defined puncturing pattern.

The puncturer 240 may puncture πₚ(0)^{th} parity bit group, πₚ(1)^{th} parity bit group, . . . , πₚ(N_{punc}_{_{—}}_{group}−1)^{th} parity bit group by group. In other words, the puncturer 240 may puncture all parity bits included in each of πₚ(0)^{th} parity bit group, πₚ(1)^{th} parity bit group, . . . , πₚ(N_{punc}_{_{—}}_{group}−1)^{th} parity bit group.

For example, it is assumed that N_{punc}=720, and the puncturing pattern is defined as shown in Table 5. In this case, the number of parity bits to be punctured is divided exactly by the interval at which a pattern of columns is repeated without any remainder, and the quotient becomes ‘2’.

Accordingly, the puncturer 240 may determine that 2 parity bit groups are to be punctured, and may determine the 18^{th} parity bit group (=P₁₈) and the 6^{th} parity bit group (=P₆) as the parity bit groups to be punctured from among 24 parity bit groups (P₀, P₁, . . . , P₂₂, P₂₃) based on the puncturing pattern as shown in Table 5. The puncturer 240 may puncture all LDPC parity bits in the 18^{th} parity bit group and the 6^{th} parity bit group.

Meanwhile, if the number of parity bits to be punctured is not divided exactly by the interval at which a pattern of columns is repeated, the puncturer 240 may determine the value which is obtained by adding ‘1’ to the quotient as the number of parity bit groups to be punctured, and may puncture at least a part of the parity bit groups at the determined position according to the pre-defined puncturing pattern.

In this case, if the quotient is ‘0’, the puncturer 240 may puncture parity bits as many as the remainder which is obtained by dividing the number of parity bits to be punctured by the internal at which a pattern of columns is repeated at the parity bit groups at the determined position according to the pre-defined puncturing pattern.

In other words, if the number of parity bits to be punctured is not divided exactly by the interval at which a pattern of columns is repeated and the quotient is ‘0’, the puncturer 240 may determine N_{punc}_{_{—group}}+1 as the number of parity bit groups to be punctured, and may puncture a part of the ₚ(N_{punc}_{_{—}}_{group})^{th} group (=Pπₚ(N_{punc}_{_{—}}_{group})) from among the parity bit groups according to the pre-defined puncturing pattern.

In this case, the puncturer 240 may puncture the parity bits as many as the remainder which is obtained by dividing the number of parity bits to be punctured by the internal at which a pattern of columns is repeated at the πₚ(N_{punc}_{_{—}}_{group}) group (=Pπₚ(N_{punc}_{_{—}}_{group})).

For example, it is assumed that N_{punc}=200 and the puncturing pattern is defined as shown in Table 6. In this case, the number of parity bits to be punctured is not divided exactly by the interval at which a pattern of columns is repeated without any remainder, and the quotient becomes ‘0’ and the remainder becomes ‘200’.

Accordingly, the puncturer 240 may determine that a part of one parity bit group is to be punctured, and may puncture the parity bits as many as the remainder of the 18^{th} parity bit group (=P₁₈), that is, 200 bits, from among 24 parity bit groups (P₀, P₁, . . . , P₂₂, P₂₃) based on the puncturing pattern as shown in Table 6.

Meanwhile, if the quotient is higher than ‘1’, the puncturer 240 may puncture the parity bits as many as the remainder which is obtained by dividing the number of parity bits to be punctured by the internal at which a pattern of columns is repeated at the last parity group from among parity bit groups at the determined position according to the pre-defined puncturing pattern, and may puncture the remaining parity bit groups by group.

In other words, if the number of parity bits to be punctured is not divided exactly by the interval at which a pattern of columns is repeated and the quotient is higher than 1′, the puncturer 240 may determine N_{punc}_{_{—}}_{group}+1 as the number of parity bit groups to be punctured, and may determine the πₚ(0)^{th} group (=Pπₚ(0)), the πₚ(1)^{th} group (=Pπₚ(1)), . . . , the πₚ(N_{punc}_{_{—}}_{group}−1)^{th} group (=Pπₚ(N_{punc}_{_{—}}_{group}−1)), and the πₚ(N_{punc}_{_{—}}_{group})^{th} group (=Pπₚ(N_{punc}_{_{—}}_{group})) from among the parity bit groups as the parity bit groups to be punctured based on the pre-defined puncturing pattern.

In this case, the puncturer 240 may perform puncturing by group with respect to the πₚ(0)^{th} group, the πₚ(1)^{th} group, . . . , and the πₚ(N_{punc}_{_{—}}_{group}−1)^{th} group, and may puncture the parity bits as many as the remainder with respect to the πₚ(N_{punc}_{_{—}}_{group})^{th} group.

For example, it is assumed that N_{punc}=800, and the puncturing pattern is defined as shown in Table 7.

In this case, the number of parity bits to be punctured is not divided exactly by the interval at which a pattern of columns is repeated without any remainder, and the quotient becomes ‘2’ and the remainder becomes ‘80’.

Accordingly, the puncturer 240 may determine that 3 parity bit groups are to be punctured, and based on the puncturing pattern as shown in Table 7, may determine the 4^{th} parity bit group (=P₄), the 11^{th} parity bit group (=P₁₁), and the 20^{th} parity bit group (=P₂₀) as the parity bit groups to be punctured from among 24 parity bit groups (P₀, P₁, . . . , P₂₂, P₂₃).

In this case, the puncturer 240 may puncture all LDPC parity bits included in the corresponding parity bit groups with respect to the 4^{th} parity bit group and the 11^{th} parity bit group, and may puncture 80 bits in the 20^{th} parity bit group which is the last parity bit group from among the parity bit groups which are determined to be punctured.

As such, if the number of parity bits to be punctured is not divided exactly by the interval at which a pattern of columns is repeated, the parity bits as many as N_{punc}−360 N_{punc}_{_{—}}_{group} are punctured in the πₚ(N_{punc}_{_{—}}_{group})th group (=Pπₚ(N_{punc}_{_{—}}_{group})).

The puncturer 240 may calculate the number of LDPC parity bit groups to be punctured in a group unit, and puncture as many parity bit groups as the number of calculated parity bit groups from among a plurality of parity bit groups constituting the LDPC parity bits based on a pre-set puncturing pattern.

In this case, the puncturer 240, based on Equation 12, may calculate the number of parity bit groups to be punctured.

$$Y = ⌊ \frac{A \times ( {N}_{L 1 post\_segmentation} - {K}_{sig} ) - B}{M} ⌋ , \qquad ( 12 )$$

where M is an interval in which a column pattern in an information word sub matrix is repeated (e.g., M=360), and M is equal to the number of LDPC parity bits included in each parity bit group. In addition, └x┘ is the greatest integer which is smaller than x, for example └1.2┘=1.

K_{sig} is the number of information word bits which are input to the zero padder 210, that is, the number of bits included in a segmented L1 signaling. N_{L1post}_{_{—}}_{segmentation} is a reference value for segmentation of an L1-post signaling, indicating the maximum number of bits which the segmented L1 signaling may have. A and B are correction factors which determine ratio of the number of bits to be additionally shortened and the number of bits to be punctured.

As to the parameter of Equation 12, it has been described above with reference to Equation 10, and the method of puncturing a parity bit group based on a pre-set puncturing pattern has been described above, and thus, explanation thereof will be omitted.

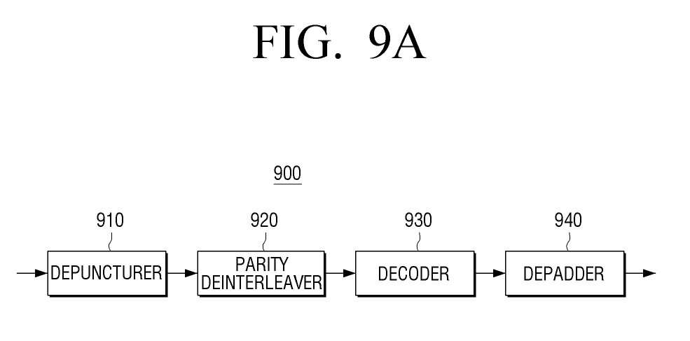

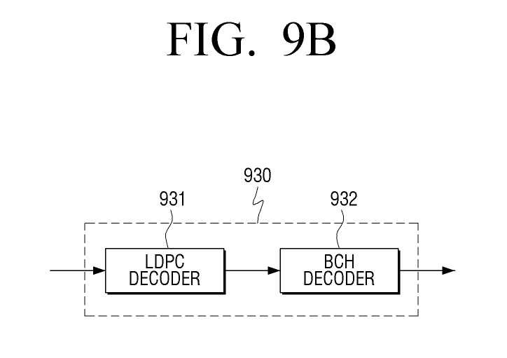

Meanwhile, the number of parity bits to be punctured may be pre-defined between the transmitting apparatus 200 and the receiving apparatus (900 of FIG. 9A). Accordingly, the transmitting apparatus 200 may pre-store information regarding the number of parity bits to be punctured, and the puncturer 240 may determine the number of parity bits to be punctured based on the information.

Meanwhile, the transmitting apparatus 200 may transmit the information regarding the number of the punctured parity bits to the receiving apparatus 900 as signaling information.

Meanwhile, the information regarding the position of the parity bit groups to be punctured and the number of bits to be punctured in the corresponding parity bit groups may be predefined between the transmitting apparatus 200 and the receiving apparatus 900. In addition, the transmitting apparatus 200 may transmit the corresponding information to the receiving apparatus 900 as signaling information, and the receiving apparatus 900 may determine the position of the parity bit groups to be punctured and the number of bits to be punctured in the corresponding parity bit groups using the received information. Further, the receiving apparatus 900 may pre-store information regarding the pre-defined parity pattern and the information regarding the number of parity bits to be punctured, and may determine the position of the parity bit groups to be punctured and the number of bits to be punctured in the corresponding parity bit groups using the information.

The puncturer 240 may remove at least one zero bit which has been padded by the zero padder 210. Specifically, the puncturer 240 may remove at least one zero bit padded by the zero padder 210 from the plurality of LDPC codewords based on the padding location of zero bits and the number of padded zero bits.

Meanwhile, the information regarding the position of the padded zero bit and the number of padded zero bit may be predefined between the transmitting apparatus 200 and the receiving apparatus 900. In addition, the transmitting apparatus 200 may transmit the corresponding information to the receiving apparatus 900 as signaling information

The bits constituting each of the LDPC codewords, which are output from the puncturer 240, may be transmitted to the receiving apparatus. For example, the transmitting apparatus 200 may modulate the bits output from the puncturer 240, map the bits onto an OFDM frame, and transmit the bits to the receiving apparatus (not shown). In this case, the L1-post signaling may be mapped onto a preamble of the OFDM frame along with the L1-pre signaling.

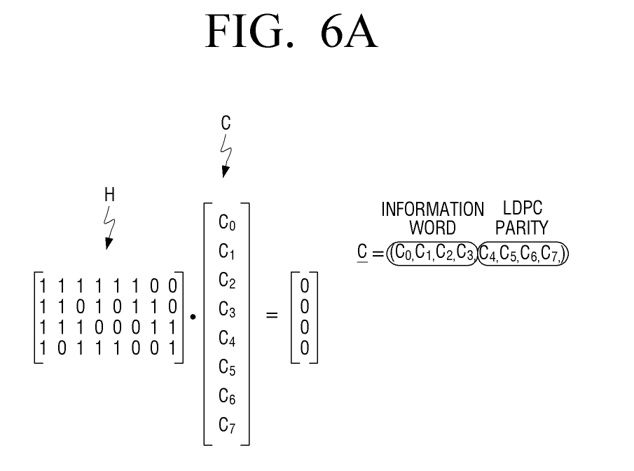

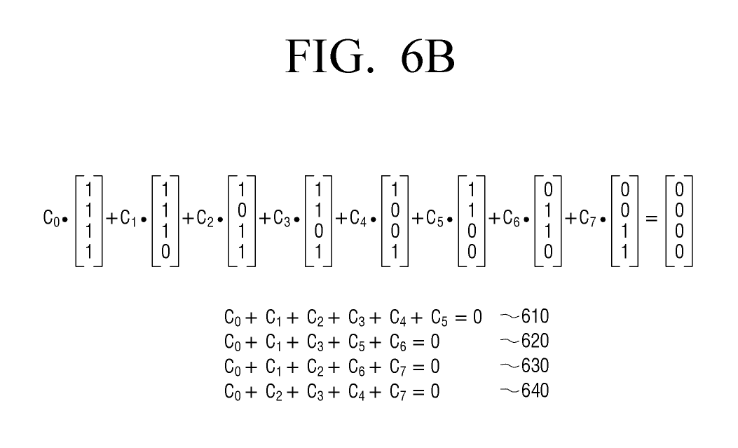

Hereinafter, a reason why the puncturing pattern is defined as shown in Tables 5 to 12 will be explained with reference to FIGS. 6A and 6B.

As shown in FIG. 6A, an LDPC codeword C may be generated such that C multiplied by the parity check matrix H is 0. That is, H·C^{T}=0. Accordingly, c₀, c₁, c₂, c₃ of an LDPC codeword C=(c₀, c₁, c₂, c₃, c₄, c₅, c₆, c₇) may be information word bits, and c₄, c₅, c₆, c₇ may be LDPC parity bits.

H·C^{T}=0 may be expressed as shown in FIG. 6B. That is, as shown in FIG. 6B, a product of the parity check matrix H and the LDPC codeword C may be expressed by a sum of products of each of the encoded bits constituting the LDPC codeword and each of the columns of the parity check matrix. Accordingly, H·C^{T}=0 may be expressed by four equations 610 to 640.

In the case of the shortening, as long as locations of bits to be shortened are known, the receiving side can know that a bit of a value 0 exists in the corresponding location. However, in the case of the puncturing, even when locations of bits to be punctured are known, it cannot be known whether the bit of the corresponding location has a value 0 or 1. Therefore, the receiving side processes the bit as an unknown value.

Accordingly, since the puncturing may influence the equation of a row where 1 exists in a column of a parity check matrix which is related to a bit to be punctured, a property of rows where 1 exists in a column related to the bit to be punctured should be considered in determining the bit to be punctured.

Accordingly, in the exemplary embodiment, when a parity check matrix used in LDPC encoding may be defined according to Table 4, parity bit groups are punctured in such an order that high decoding performance can be guaranteed even when the parity bit groups are punctured in relation to the parity check matrix, and examples of the puncturing order are as shown in Tables 5 to 12.

As described above, M number of continuous bits in an LDPC codeword have a same degree and a same cycle property. Accordingly, puncturing in a unit of a group based on an optimal puncturing pattern can guarantee the same performance as puncturing in a unit of a bit based on an optimal puncturing pattern. Accordingly, when puncturing is performed in a unit of a group as in the exemplary embodiment, the same performance as puncturing in a unit of a bit can be guaranteed, and also, many bits can be punctured at once. Therefore, complexity can be reduced and efficiency can be improved.

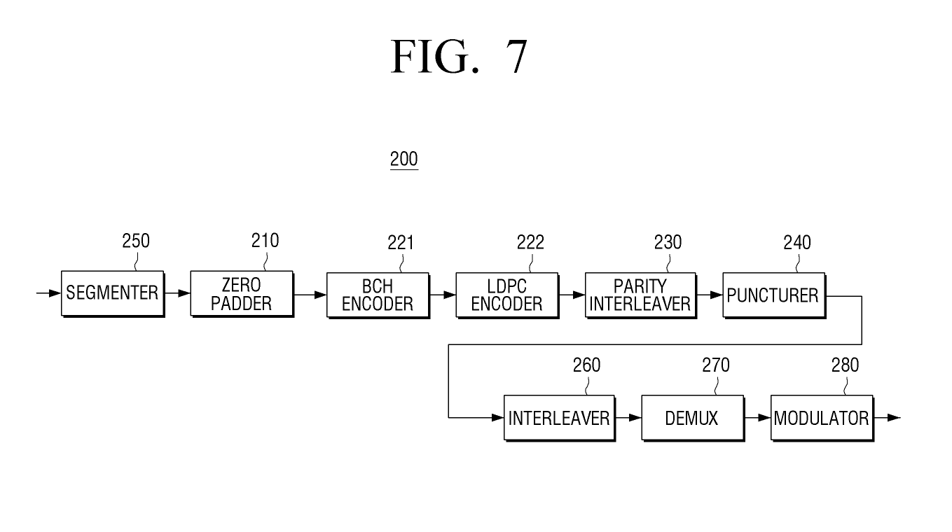

FIG. 7 is a block diagram to illustrate a detailed configuration of a transmitting apparatus according to an exemplary embodiment. As shown in FIG. 7, the transmitting apparatus 200 includes a segmenter 250, a zero padder 210, an encoder 220, a parity interleaver 230, a puncturer 240, an interleaver 260, a demux 270, and a modulator 280. Herein, the zero padder 210, the encoder 220, the parity interleaver 230, and the puncturer 240 are the same as those of FIGS. 1 to 6 and thus a redundant explanation is omitted.

The segmenter 250 segments an L1-post signaling and outputs a plurality of segmented L1-post signalings to the zero padder 210.

Specifically, since the length of the L1-post signaling is variable, the segmenter 240 segments the L1-post signaling into a plurality of L1-post signalings such that each segmented L1-post signaling can have a length less than a certain value, and outputs the plurality of segmented L1-post signalings to the zero padder 210. Accordingly, the zero padder 210 can pad at least one zero bit to a segmented L1 post signaling.

However, when the L1-post signaling is formed of less number of bits than a certain value, the segmenter 240 may not segment the L1-post signaling.

The interleaver 260 interleaves the bits output from the puncturer 240 and outputs the interleaved bits to the demux 270. That is, the interleaver 260 interleaves each of the LDPC codewords output from the puncturer 240 and outputs the plurality of interleaved LDPC codewords to the demux 270.

In this case, the interleaver 260 may interleave the bits output from the puncturer 240 by using N_{c} number of columns formed of Nᵣ number of rows. Specifically, the interleaver 260 may perform interleaving by writing the bits output from the puncturer 240 on the first column to N_{c}^{th} column in a column direction, and reading the bits from the first row of the plurality of columns where the bits are written to Nᵣ^{th} row in a row direction. Accordingly, the bits written on a same row of each column are output in sequence so that the bits are rearranged in a different order from that before being interleaved.

The interleaver 260 may perform interleaving selectively according to a modulation scheme. For example, the interleaver 260 may perform interleaving only when the modulation scheme is 16-QAM, 64-QAM, or 256-QAM.

The number of columns N_{c} and the number of rows Nᵣ constituting the interleaver 260 may be changed according to a code rate and a modulation scheme. For example, when the code rate of the LDPC code is 7/15, the number of columns N_{c} is the same as the modulation degree (or order) of the L1-post signaling, and the number of rows Nᵣ is the number of bits of the LDPC codeword output from the puncturer 240 divided by N_{c}. Here, the modulation degree is the number of bits constituting a modulation symbol. When the modulation scheme is BPSK, QPSK, 16-QAM, 64-QAM, or 256-QAM, the modulation degree may be 1, 2, 4, 6, or 8, respectively. For example, when the number of bits of the LDPC codeword output from the puncturer 240 is N_{L1post}, and the modulation scheme is 16-QAM, 64-QAM, and 256-QAM, the modulation degree is 4, 6, and 8, respectively. Therefore, the number of columns N_{c} may be 4, 6, and 8, and the number of rows Nᵣ may be N_{L1post}/4, N_{L1post}/6, and N_{L1post}/8, respectively.

The demux (or demultiplexer) 270 may demultiplex the bits output from the interleaver 260 and may output the demultiplexed bits to the modulator 280. That is, the demux 270 may demultiplex the bits constituting each of the LDPC codewords output from the interleaver 260, and may output the bits to the modulator 280.

Specifically, the demux 270 may perform bit-to-cell conversion with respect to the bits output from the interleaver 260, and may demultiplex the bits output from the interleaver 260 into a cell (or a data cell) formed of a certain number of bits.

For example, the demux 270 may convert the interleaved LDPC codeword bits into a cell by outputting the interleaved LDPC codeword bits output from the interleaver 260 to a plurality of sub streams in sequence, and may output the cell. In this case, bits having a same index in each of the plurality of sub streams may constitute a same cell.

Here, the number of sub streams is the same as the number of bits constituting a cell. For example, when the modulation scheme is BPSK, QPSK, 16-QAM, 64-QAM, 256-QAM, the number of sub streams is 1, 2, 4, 6, 8 and the number of cells is N_{L1post}, N_{L1post}/2, N_{L1post}/4, N_{L1post}/6, N_{L1post}/8, respectively.

The demux 270 may selectively demultiplex according to a modulation scheme. For example, the demux 270 may not demultiplex when the modulation scheme is BPSK.

The modulator 280 may modulate the cells output from the demux 270. Specifically, the modulator 280 may modulate the cells output from the demux 270 by mapping the cells onto constellation points by using various modulation schemes such as BPSK, QPSK, 16-QAM, 64-QAM, 256-QAM, etc. When the modulation scheme is BPSK, QPSK, 16-QAM, 64-QAM, 256-QAM, the number of bits constituting a modulated cell (that is, a modulation symbol) may be 1, 2, 4, 6, 8.

The transmitting apparatus 200 may transmit the modulation symbol to a receiving apparatus. For example, the transmitting apparatus 200 may map the modulation symbol onto an OFDM frame by using an OFDM scheme, and may transmit the modulation symbol to the receiving apparatus via an allocated channel. In this case, the modulation symbol of the L1-post signaling may be mapped onto a preamble of the OFDM frame.

In the above-described example, the zero padder 210 is placed before the BCH encoder 221. However, this is merely an example. That is, the zero padder 210 may be placed between the BCH encoder 221 and the LPDC encoder 222 as shown in FIG. 8. In this case, the elements of FIG. 8 are the same as the elements of FIG. 7 in their respective operations except the arrangements of the elements. Accordingly, a difference will mainly be explained below with reference to FIGS. 9A and 9B.

Referring to FIG. 8, the BCH encoder 221 may generate a plurality of BCH codewords by performing BCH encoding with respect to each of the segmented L1-post signalings, and may output the BCH codewords to the zero padder 210.

The zero padder 210 adds zero bits to a BCH codeword and outputs a BCH codeword to which the zero bits are added, to the LDPC encoder 222. For example, when the length of a BCH codeword is N_{bch} (=K_{sig}+K_{bhc}_{_{—}}_{panty}), the length of an information word required in the LDPC encoding is K_{ldpc}, and K_{ldpc}>N_{bch}, the zero padder 210 may pad zero bits of K_{ldpc}−N_{bch} to the BCH codeword.

The LDPC encoder 222 may generate a plurality of LDPC codewords by performing LDPC encoding with respect to each of the BCH codewords padded with the zero bits, and may output the LDPC codewords to the parity interleaver 230. In this case, since a BCH codeword padded with the zero bits is formed of K_{ldpc} bits, the LDPC encoder 222 may generate an LDPC codeword having the length of N_{ldpc} by performing LDPC encoding with respect to the BCH codeword padded with zero bits.

In the above-described example, the L1-post signaling is segmented and the plurality of segmented L1-post signalings are processed by each of the elements of the transmitting apparatus 200. However, this is merely an example. That is, when the length of the L1-post signaling is less than a certain value, the L1-post signaling may not be segmented. In this case, each of the elements of the transmitting apparatus 200 can process the L1-post signaling.

According to another exemplary embodiment, the transmitting apparatus 200 may further include a controller (not shown) to control operations of the transmitting apparatus 200, and a storage (not shown) to store information related to the operations of the transmitting apparatus 200.

Specifically, the storage may store a variety of information. For example, the storage may store information on the number of zero bits to be padded and the padding location of the zero bits, information on a configuration of a parity check matrix, and information on a same puncturing pattern.

The controller controls an overall operation of the transmitting apparatus 200. Specifically, the controller may calculate various parameters for controlling an operation performed by each of the elements of the transmitting apparatus 200, and may provide the parameters to each of the elements. Accordingly, the zero padder 210, the encoder 220, the parity interleaver 230, the puncturer 240, the segmenter 250, the interleaver 260, the demux 270, and the modulator 280 may perform operations by using information provided from the controller.

For example, the controller may provide information on the location and number of zero bits to be padded to the zero padder 210, and may provide information on the code rate, the length of a codeword, and the parity check matrix to the encoder 220. In addition, the controller may provide information on the parity interleaving method to the parity interleaver 230, and may provide information on the puncturing pattern, the number of parity bit groups to be punctured, and the location and number of zero bits padded by the zero padder 210 to the puncturer 240. In addition, the controller may provide information on the interleaving method to the interleaver 260, provide information on the demultiplexing method to the demux 270, and provide information on the modulating method to the modulator 280.

FIGS. 9A and 9B are block diagrams to illustrate a configuration of a receiving apparatus according to an exemplary embodiment. Referring to FIG. 9A, the receiving apparatus 900 includes a depuncturer 910, a parity deinterleaver 920, a decoder 930, and a depadder 940.

The depuncturer 910 adds a specific value to a channel value regarding a signal received from the transmitting apparatus 200, and outputs the signal to the parity deinterleaver 920. Herein, the channel value regarding the received signal may be a Log Likelihood Ratio (LLR) value, for example.

Specifically, the depuncturer 910 is an element corresponding to the zero padder 210 and the puncturer 240 of the transmitting apparatus 200, and may perform an operation corresponding to those of the zero padder 210 and the puncturer 240.

First, the depuncturer 910 may insert an LLR value corresponding to the LDPC parity bits punctured by the puncturer 240 into the LLR value. Herein, the LLR value corresponding to the puncturered bits may be 0.

To do so, the depuncturer 910 may determine the number of parity bits which are punctured by the puncturer 240.

In this case, the number of the parity bits to be punctured may be pre-defined between the transmitting apparatus 200 and the receiving apparatus 900. Meanwhile, the transmitting apparatus 200 may transmit the information regarding the number of the punctured parity bits to the receiving apparatus 900 as signaling information. In this case, the depuncturer 910 may determine the number of parity bits which are punctured by the puncturer 240 using the received information.

In addition, the depuncturer 910 may determine the position of the punctured parity bit groups and the number of the punctured bits in the corresponding parity bit groups based on the pre-defined puncturing pattern and the number of the punctured parity bits.

In other words, the depuncturer 910 may determine the position of the punctured parity bit groups and the number of the punctured bits in the corresponding parity bit groups by using the method of determining the position of the punctured parity bit groups and the number of the punctured bits in the corresponding parity bit groups which is used in the puncturer 240, which has been already described in detail with respect to the transmitting apparatus 200.

Subsequently, the depuncturer 910 may add a specific value to a channel value regarding a received signal based on the location of the punctured parity bit groups and the number of punctured bits in the corresponding parity bit groups.

In other words, the depuncturer 910 may insert an LLR value as many as the number of the punctured bits in the corresponding parity bit groups at the location of the punctured parity bit groups. Herein, the LLR value corresponding to the punctured bits may be ‘0’.

Meanwhile, in the above exemplary embodiment, the depuncturer 910 calculates the location of the punctured parity bit groups and the number of punctured bits in the corresponding parity bit groups, but this is only an example. The corresponding information may be pre-stored in the receiving apparatus 900 or may be provided by the transmitting apparatus 200.

As described above, information on the location and number of bits punctured by the puncturer 240 may be provided from the transmitting apparatus 200 or may be pre-stored in the receiving apparatus 900. In addition, the receiving apparatus 900 may calculate the location and number of bits punctured by the puncturer 240.

For example, the locations of the punctured bits may be defined according to a modulation scheme as shown in Tables 5 to 12, and the number of punctured bits may be the value calculated according to Equation 10 or, a product of the number of groups Y calculated according to Equation 12 and the number of LDPC parity bits included in each group, that is, Y×360. Accordingly, the depuncturer 910 may insert a corresponding number of LLR values into the locations where the punctured LDPC parity bits have existed.

In addition, the depuncturer 910 may add an LLR value corresponding to the zero bit which has been added by the zero padder 210 and then has been removed by the puncturer 240 to the LLR value. In this case, the LLR value corresponding to the zero bit which has been padded and removed, that is, the shortened zero bit may be +∞ or −∞, but are not limited thereto. The LLR values corresponding to the shortened zero bit may be a maximum value or a minimum value of LLR which is allowed in a receiving system.

To achieve this, the receiving apparatus 900 may pre-store the information on the number, locations, and bit values of the bits shortened in the transmitting apparatus 200, or may receive the information from the transmitting apparatus 200. Accordingly, the depuncturer 910 may insert a corresponding number of LLR values to the locations where the shortened zero bits have existed.

The parity deinterleaver 920 performs parity deinterleaving with respect to the output value of the depuncturer 910, and outputs the value to the decoder 930.

Specifically, the parity deinterleaver 920 is an element corresponding to the parity interleaver 230 of the transmitting apparatus 200 and performs an operation corresponding to that of the parity interleaver 230. That is, the parity deinterleaver 920 may perform the interleaving operation of the parity interleaver 230 inversely and may deinterleave an LLR value corresponding to an LDPC parity bit from among the LLR values output from the depuncturer 910. However, the parity deinterleaver 920 of the receiving apparatus 900 may be omitted according to decoding method and operation of the decoder 930.

The decoder 930 may perform LDPC decoding and BCH decoding based on the output value of the parity deinterleaver 920, and may output bits which are generated as a result of the decoding to the depadder 940.

Specifically, the decoder 930 is an element corresponding to the encoder 220 of the transmitting apparatus 200 and may perform an operation corresponding to that of the encoder 220. To achieve this, the decoder 930 may include an LDPC decoder 931 and a BCH decoder 932 as shown in FIG. 9B.

Specifically, the LDPC decoder 931 is an element corresponding to the LDPC encoder 222 and performs an operation corresponding to that of the LDPC encoder 222. For example, the LDPC decoder 931 may correct an error by performing LDPC decoding by using the LLR value output from the parity deinterleaver 920 based on an iterative decoding scheme based on a sum-product algorithm.

Herein, the sum-product algorithm refers to an algorithm by which messages (e.g., LLR value) are exchanged through an edge on a bipartite graph of a message passing algorithm, and an output message is calculated from messages input to variable nodes or check nodes, and is updated.

The BCH decoder 932 performs BCH decoding with respect to the output value of the LDPC decoder 931. That is, the BCH decoder 932 is an element corresponding to that of the BCH encoder 212 and performs an operation corresponding to the BCH encoder 212.

Specifically, since each of the output values of the LDPC decoder 931 is formed of a segmented L1-post signaling, at least one zero bit added to the segmented L1-post signaling, and a plurality of bit strings including BCH parity bits, the BCH decoder 932 may correct the error by using the BCH parity bits, and may output the plurality of bit strings each including the segmented L1-post signaling and the at least one zero bit added to the segmented L1-post signaling, to the depadder 940.

The LDPC decoding and BCH decoding may be performed in various well-known methods.

The depadder 940 may remove zero bits from the output value of the decoder 930 and may output the value. Specifically, the depadder 940 is an element corresponding to the zero padder 210 of the transmitting apparatus 200 and may perform an operation corresponding to that of the zero padder 210. That is, the depadder 940 may remove the at least one zero bit which has been added by the zero padder 210 from a bit string output from the BCH decoder 932, and may output the segmented L1-post signaling. To achieve this, the information on the location and number of the at least one zero bit added by the zero padder 210 may be provided from the transmitting apparatus 200 or may be pre-stored in the receiving apparatus 900.

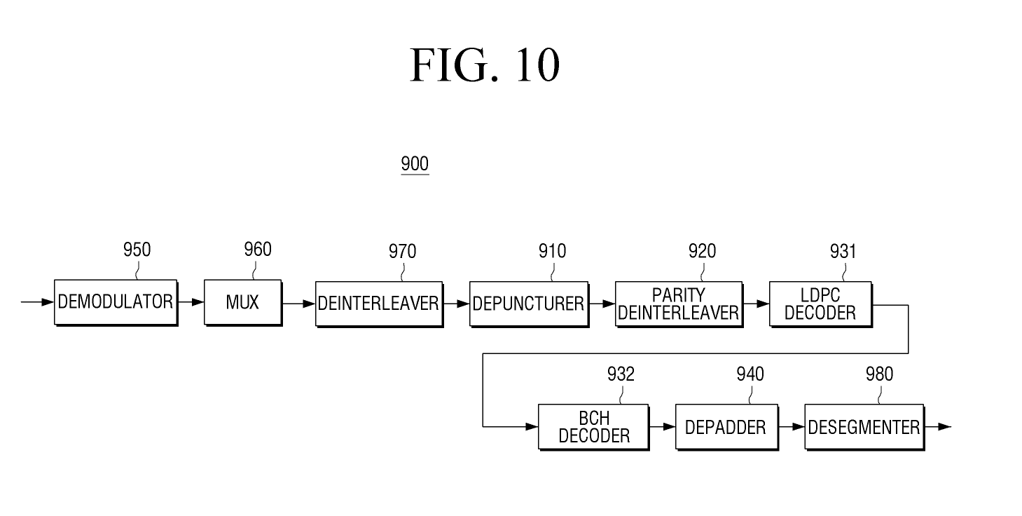

FIG. 10 is a block diagram to illustrate a detailed configuration of a receiving apparatus according to an exemplary embodiment. Referring to FIG. 10, the receiving apparatus 900 may include a demodulator 950, a mux 960, a deinterleaver 970, a depuncturer 910, a parity deinterleaver 920, an LDPC decoder 931, a BCH decoder 932, a depadder 940, and a desegmenter 980. Here, since the depuncturer 910, the parity deinterleaver 920, the LDPC decoder 931, the BCH decoder 932, and the depadder 940 have been described with reference to FIGS. 9A and 9B, a redundant description thereof is omitted.

The demodulator 950 receives and demodulates a signal transmitted from the transmitting apparatus 200. Specifically, the demodulator 950 generates a channel value regarding the received signal by demodulating the received signal, and outputs the channel value to the mux 960.

Here, there are various methods for determining the channel value. For example, a method for determining an LLR value is an example of the method for determining the channel value.

For example, the LLR value may indicate a log value for a ratio of a probability that the bit transmitted from the transmitting apparatus 200 is 0 and the probability that the bit is 1. In addition, the LLR value may be a bit value which is determined by a hard decision, or may be a representative value which is determined according to a section to which a probability that the bit transmitted from the transmitting apparatus 200 is 0 or 1 belongs.

The mux (or multiplexer) 960 multiplexes the output value of the demodulator 950 and outputs the value to the deinterleaver 970.

Specifically, the mux 960 is an element corresponding to the demux 270 of the transmitting apparatus 200 and performs an operation corresponding to that of the demux 270. That is, the mux 950 may convert the output value of the demodulator 940 from a cell to bits, and may rearrange the LLR values in a unit of a bit.

The deinterleaver 970 deinterleaves the output value of the mux 960 and outputs the value to the depuncturer 910. Accordingly, the depuncturer 910 may add a specific value to the output value of the deinterleaver 960. Specifically, the deinterleaver 970 is an element corresponding to the interleaver 120 of the transmitter apparatus 100 and performs an operation corresponding to that of the interleaver 260 of the transmitting apparatus 200 and performs an operation corresponding to the interleaver 260. That is, the deinterleaver 970 deinterleaves the output value of the mux 960 by performing the interleaving operation of the interleaver 260 inversely.

The desegmenter 980 desegments the output value of the depadder 940.

Specifically, the desegmenter 980 is an element corresponding to the segmenter 250 of the transmitting apparatus 200 and may perform an operation corresponding to that of the segmenter 250. That is, since a plurality of bit strings output from the depadder 940, that is, the plurality of segmented L1-post signalings have been segmented by the transmitting apparatus 200, the desegmenter 980 may generate the L1-post signaling in the original state that existed before the L1-post signaling was segmented by desegmenting the plurality of segmented L1 post signalings, and may output the L1-post signaling.

The information which is necessary for the operation of each of the elements in FIGS. 9A to 11 may be provided from the transmitting apparatus 200 or may be pre-stored in the receiving apparatus 900. For example, the information necessary for the operation of each of the elements may be the multiplexing method performed in the mux 960, the deinterleaving method performed in the deinterleaver 970, the location and number of LLR values added by the depuncturer 910, the deinterleaving method performed in the parity deinterleaver 920, information used in the decoder 930 for the LDPC decoding and the BCH decoding (e.g., the code rate, the length of an LDPC codeword, information on a parity check matrix, the length of a BCH codeword, etc.), or information on the order in which the segmented L1-post signalings are desegmented by the desegmenter 980.

When the transmitting apparatus 200 processes and transmits an L1-post signaling by using the elements shown in FIG. 7, the receiving apparatus 900 may process the L1-post signaling by using the elements shown in FIG. 10.

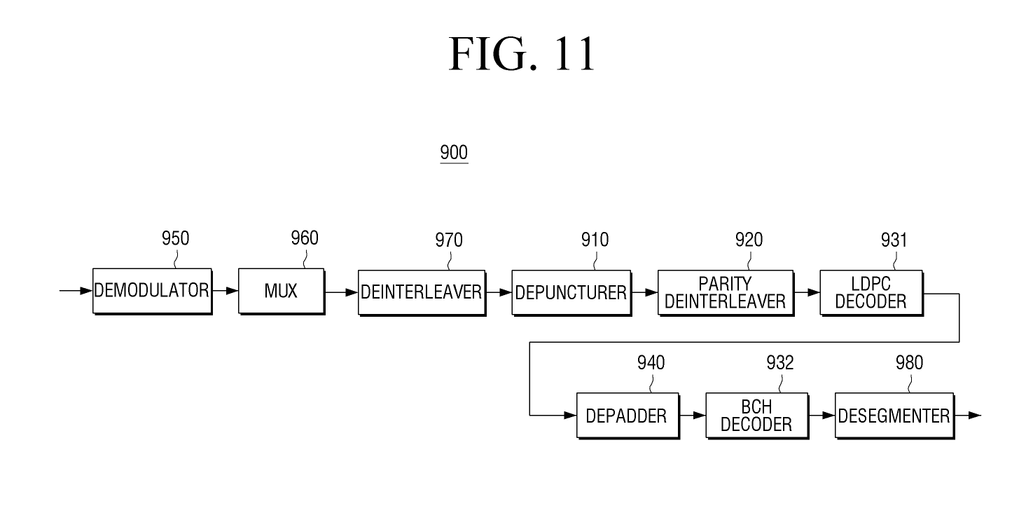

However, when the transmitting apparatus 200 uses the elements shown in FIG. 8, the receiving apparatus 900 may process the L1-post signaling by using the elements shown in FIG. 11. In this case, the elements of FIG. 11 are the same as the elements of FIG. 10 in their respective operations except the arrangement of the elements. Accordingly, a difference will mainly be explained below.

The LDPC decoder 931 may output the bits which are generated as a result of the decoding to the depadder 940. In this case, the bits input to the depadder 940 may be formed of a plurality of bit strings each of which includes a segmented L1-post signaling, at least one zero bit padded to the segmented L1-post signaling, and BCH parity bits.

The depadder 940 may remove the zero bit from the bits output from the LDPC decoder 931 and may output the bits to the BCH decoder 932.

Accordingly, since the bits input to the BCH decoder 932 are formed a plurality of bit strings each of which includes the segmented L1-post signaling and the BCH parity bits, the BCH decoder 932 may correct an error by using the BCH parity bits and may output the segmented L1-post signaling to the desegmenter 980.

In the above-described example, the L1-post signaling is segmented and transmitted to the receiving apparatus 900. However, this is merely an example. That is, when the L1-post signaling has a length less than a certain value, the L1-post signaling may be transmitted to the receiving apparatus 900 without being segmented. In this case, since the bit strings input to the desegmenter 980 may be formed of the L1-post signaling, the desegmenter 980 may output the L1-post signaling without desegmenting separately.

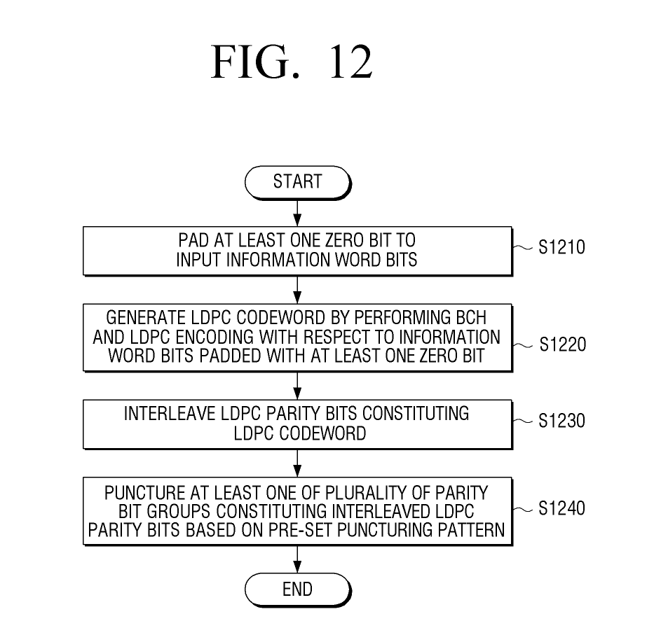

FIG. 12 is a flowchart to illustrate a puncturing method of a transmitting apparatus according to an exemplary embodiment.

First, the transmitting apparatus pads at least one zero bit to input information word bits (S1210).

After that, the transmitting apparatus generates an LDPC codeword by performing BCH encoding and LDPC encoding with respect to the information word bits to which at least one zero bit is padded (S1220). Here, the transmitting apparatus may generate an LDPC codeword formed of 16200 bits by performing LDPC encoding at a code rate of 7/15.

In addition, the transmitting apparatus may perform LDPC encoding based on a parity check matrix formed of an information word sub matrix and a parity sub matrix. The information word sub matrix is formed of 21 column groups each including 360 columns, and a location of a value 1 in a 0^{th} column of each of the column groups may be defined as shown in Table 4.

The transmitting apparatus interleaves LDPC parity bits constituting the LDPC codeword (S1230).

In addition, the transmitting apparatus punctures at least a part of the interleaved LDPC parity bits based on a pre-set puncturing pattern (S1240).

Specifically, the transmitting apparatus may determine parity bit groups to be punctured from among a plurality of parity bit groups constituting interleaved LDPC parity bits based on a pre-set puncturing pattern, and may puncture at least a part of the LDPC parity bits included in the determined bit group. In this case, the transmitting apparatus may puncture at least a part of the LDPC parity bits based on a different puncturing pattern according to a modulation scheme.

When the modulation scheme is BPSK or QPSK, the pre-set puncturing pattern may be defined as shown in Table 5 or 6.

In addition, when the modulation scheme is 16-QAM, the pre-set puncturing pattern may be defined as shown in Table 7 or 8.

In addition, when the modulation scheme is 64-QAM, the pre-set puncturing pattern may be defined as shown in Table 9 or 10.

In addition, when the modulation scheme is 256-QAM, the pre-set puncturing pattern may be defined as shown in Table 11 or 12.

The detailed puncturing method has been described above with reference to FIGS. 1 to 8.

According to an exemplary embodiment, a depuncturing method of a receiving apparatus may be provided to be consistent with the above descriptions with regard to the receiving apparatus 900. Since the depuncturing method is the same or similar to the functions of the elements of FIGS. 9A-11, the redundant descriptions about the depuncturing method are omitted.

A non-transitory computer readable medium, which stores a program for performing the puncturing methods and depuncturing methods according to various exemplary embodiments in sequence, may be provided.

The non-transitory computer readable medium refers to a medium that stores data semi-permanently rather than storing data for a very short time, such as a register, a cache, and a memory, and is readable by an apparatus. Specifically, the above-described various applications or programs may be stored in a non-transitory computer readable medium such as a compact disc (CD), a digital versatile disk (DVD), a hard disk, a Blu-ray disk, a universal serial bus (USB), a memory card, and a read only memory (ROM), and may be provided.

The elements represented by blocks as illustrated in FIGS. 2, 3 and 7-11 may be embodied as various numbers of hardware, software and/or firmware structures that execute respective functions described above, according to an exemplary embodiment. For example, these elements may use a direct circuit structure, such as a memory, processing, logic, a look-up table, etc. that may execute the respective functions through controls of one or more microprocessors or other control apparatuses. Also, these elements may be specifically embodied by a program or a part of code, which contains one or more executable instructions for performing specified logic functions. Also, at least one of these elements may further include a processor such as a central processing unit (CPU) that performs the respective functions, a microprocessor, or the like. Although a bus is not illustrated in the above block diagrams of FIGS. 2, 3 and 7-11, communication between the respective blocks may be performed via the bus.

The foregoing exemplary embodiments and advantages are merely exemplary and are not to be construed as limiting the present inventive concept. The exemplary embodiments can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A transmitting apparatus comprising:
a zero padder configured to pad at least one zero bit to input bits;
an encoder configured to generate a Low Density Parity Check (LDPC) codeword by performing LDPC encoding with respect to the bits to which the at least one zero bit is padded;
a parity interleaver configured to interleave LDPC parity bits constituting the LDPC codeword; and
a puncturer configured to puncture at least a part of the interleaved LDPC parity bits based on a pre-set puncturing pattern.

2. The transmitting apparatus of claim 1, wherein the encoder generates the LDPC codeword formed of 16200 bits by performing the LDPC encoding at a code rate of 7/15.

3. The transmitting apparatus of claim 2, wherein the encoder performs the LDPC encoding based on a parity check matrix formed of an information word sub matrix and a parity sub matrix, and
wherein the information word sub matrix is formed of 21 column groups each of which is formed of 360 columns, and a location of a value 1 in 0^{th} column of each of the column groups is defined by a table presented below:

| | Index of row where 1 is |
|---|---|
| i | located in the 0th column of ith column group |
| 0 | 432 655 893 942 1285 1427 1738 2199 2441 2565 2932 3201 4144 |
| | 4419 4678 4963 5423 5922 6433 6564 6656 7478 7514 7892 |
| 1 | 220 453 690 826 1116 1425 1488 1901 3119 3182 3568 3800 |
| | 3953 4071 4782 5038 5555 6836 6871 7131 7609 7850 8317 8443 |
| 2 | 300 454 497 930 1757 2145 2314 2372 2467 2819 3191 3256 3699 |
| | 3984 4538 4965 5461 5742 5912 6135 6649 7636 8078 8455 |
| 3 | 24 65 565 609 990 1319 1394 1465 1918 1976 2463 2987 3330 3677 |
| | 4195 4240 4947 5372 6453 6950 7066 8412 8500 8599 |
| 4 | 1373 4668 5324 7777 |
| 5 | 189 3930 5766 6877 |
| 6 | 3 2961 4207 5747 |
| 7 | 1108 4768 6743 7106 |
| 8 | 1282 2274 2750 6204 |
| 9 | 2279 2587 2737 6344 |
| 10 | 2889 3164 7275 8040 |
| 11 | 133 2734 5081 8386 |
| 12 | 437 3203 7121 |
| 13 | 4280 7128 8490 |
| 14 | 619 4563 6206 |
| 15 | 2799 6814 6991 |
| 16 | 244 4212 5925 |
| 17 | 1719 7657 8554 |
| 18 | 53 1895 6685 |
| 19 | 584 5420 6856 |
| 20 | 2958 5834 8103 |

4. The transmitting apparatus of claim 1, wherein the puncturer determines at least one parity bit group to be punctured based on the pre-set puncturing pattern, from among a plurality of parity bit groups constituting the interleaved LDPC parity bits, and punctures at least a part of the interleaved LDPC parity bits included in the determined parity bit group.

5. The transmitting apparatus of claim 1, wherein the puncturer punctures at least a part of the interleaved LDPC parity bits based on a puncturing pattern which differs according to a modulation scheme.

6. The transmitting apparatus of claim 1, wherein the pre-set puncturing pattern is defined as in a table presented below when a modulation scheme is BPSK or QPSK:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| BPSK/ | 7/15 | 18 | 6 | 11 | 3 | 21 | 0 | 14 | 8 | 16 | 19 | 22 | 2 |
| QPSK | | 10 | 5 | 13 | 23 | 9 | 17 | 4 | 15 | 1 | 20 | 12 | 7 |

where πₚ(j) is an index of a parity bit group which is punctured j^{th}.

7. The transmitting apparatus of claim 1, wherein the pre-set puncturing pattern is defined as in a table presented below when a modulation scheme is BPSK or QPSK:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| BPSK/ | 7/15 | 18 | 6 | 11 | 4 | 0 | 14 | 22 | 9 | 2 | 16 | 20 | 12 |
| QPSK | | 7 | 21 | 17 | 3 | 10 | 1 | 15 | 8 | 19 | 5 | 13 | 23 |

where πₚ(j) is an index of a parity bit group which is punctured j^{th}.

8. The transmitting apparatus of claim 1, wherein the pre-set puncturing pattern is defined as in a table presented below when a modulation scheme is 16-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 16 QAM | 7/15 | 4 | 11 | 20 | 18 | 7 | 15 | 13 | 23 | 1 | 9 | 6 | 17 |
| | | 3 | 12 | 19 | 0 | 22 | 8 | 14 | 2 | 21 | 16 | 10 | 5 |

where πₚ(j) is an index of a parity bit group which is punctured j^{th}.

9. The transmitting apparatus of claim 1, wherein the pre-set puncturing pattern is defined as in a table presented below when a modulation scheme is 16-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 16 QAM | 7/15 | 4 | 11 | 14 | 6 | 18 | 0 | 22 | 9 | 20 | 2 | 12 | 16 |
| | | 7 | 19 | 15 | 1 | 10 | 5 | 21 | 13 | 3 | 17 | 8 | 23 |

where πₚ(j) is an index of a parity bit group which is punctured j^{th}.

10. The transmitting apparatus of claim 1, wherein the pre-set puncturing pattern is defined as in a table presented below when a modulation scheme is 64-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 64 QAM | 7/15 | 11 | 18 | 7 | 0 | 3 | 14 | 21 | 9 | 5 | 23 | 16 | 12 |
| | | 19 | 2 | 8 | 15 | 22 | 10 | 4 | 17 | 1 | 13 | 6 | 20 |

where πₚ(j) is an index of a parity bit group which is punctured j^{th}.

11. The transmitting apparatus of claim 1, wherein the pre-set puncturing pattern is defined as in a table presented below when a modulation scheme is 64-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 64 QAM | 7/15 | 18 | 6 | 0 | 13 | 3 | 9 | 21 | 11 | 16 | 20 | 2 | 8 |
| | | 5 | 14 | 17 | 22 | 10 | 19 | 1 | 7 | 15 | 4 | 12 | 23 |

where πₚ(j) is an index of a parity bit group which is punctured j^{th}.

12. The transmitting apparatus of claim 1, wherein the pre-set puncturing pattern is defined as in a table presented below when a modulation scheme is 256-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 256 QAM | 7/15 | 4 | 16 | 11 | 20 | 7 | 18 | 0 | 22 | 13 | 2 | 9 | 5 |
| | | 19 | 14 | 8 | 1 | 21 | 10 | 17 | 6 | 15 | 3 | 12 | 23 |

where πₚ(j) is an index of a parity bit group which is punctured j^{th}.

13. The transmitting apparatus of claim 1, wherein the pre-set puncturing pattern is defined as in a table presented below when a modulation scheme is 256-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 256 QAM | 7/15 | 4 | 21 | 6 | 11 | 13 | 18 | 0 | 15 | 2 | 9 | 7 | 22 |
| | | 19 | 1 | 17 | 10 | 14 | 20 | 16 | 5 | 8 | 3 | 12 | 23 |

where πₚ(j) is an index of a parity bit group which is punctured j^{th}.

14. A method for puncturing at a transmitting apparatus, the method comprising:
padding at least one zero bit to input bits;
generating a Low Density Parity Check (LDPC) codeword by performing LDPC encoding with respect to the bits to which the at least one zero bit is padded;
interleaving LDPC parity bits constituting the LDPC codeword; and
puncturing at least a part of the interleaved LDPC parity bits based on a pre-set puncturing pattern.

15. The method of claim 14, wherein the generating the LDPC codeword comprises generating an LDPC codeword formed of 16200 bits by performing the LDPC encoding at a code rate of 7/15.

16. The method of claim 15, wherein the generating the LDPC codeword comprises performing the LDPC encoding based on a parity check matrix formed of an information word sub matrix and a parity sub matrix, and
wherein the information word sub matrix is formed of 21 column groups each of which is formed of 360 columns, and a location of a value 1 in a 0^{th} column of each of the column groups is defined by a table presented below:

| | Index of row where 1 is |
|---|---|
| i | located in the 0th column of ith column group |
| 0 | 432 655 893 942 1285 1427 1738 2199 2441 2565 2932 3201 4144 |
| | 4419 4678 4963 5423 5922 6433 6564 6656 7478 7514 7892 |
| 1 | 220 453 690 826 1116 1425 1488 1901 3119 3182 3568 3800 3953 |
| | 4071 4782 5038 5555 6836 6871 7131 7609 7850 8317 8443 |
| 2 | 300 454 497 930 1757 2145 2314 2372 2467 2819 3191 3256 3699 |
| | 3984 4538 4965 5461 5742 5912 6135 6649 7636 8078 8455 |
| 3 | 24 65 565 609 990 1319 1394 1465 1918 1976 2463 2987 3330 3677 |
| | 4195 4240 4947 5372 6453 6950 7066 8412 8500 8599 |
| 4 | 1373 4668 5324 7777 |
| 5 | 189 3930 5766 6877 |
| 6 | 3 2961 4207 5747 |
| 7 | 1108 4768 6743 7106 |
| 8 | 1282 2274 2750 6204 |
| 9 | 2279 2587 2737 6344 |
| 10 | 2889 3164 7275 8040 |
| 11 | 133 2734 5081 8386 |
| 12 | 437 3203 7121 |
| 13 | 4280 7128 8490 |
| 14 | 619 4563 6206 |
| 15 | 2799 6814 6991 |
| 16 | 244 4212 5925 |
| 17 | 1719 7657 8554 |
| 18 | 53 1895 6685 |
| 19 | 584 5420 6856 |
| 20 | 2958 5834 8103 |

17. The method of claim 14, wherein the puncturing comprises determining at least one parity bit group to be punctured based on the pre-set puncturing pattern, from among a plurality of parity bit groups constituting the interleaved LDPC parity bits, and puncturing at
least a part of the interleaved LDPC parity bit groups included in the determined parity bit group.

18. The method of claim 15, wherein the puncturing comprises puncturing at least a part of the interleaved LDPC parity bits based on a puncturing pattern which differs according to a modulation scheme.

19. The method of claim 14, wherein the pre-set puncturing pattern is defined as in a table presented below when a modulation scheme is BPSK or QPSK:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| BPSK/ | 7/15 | 18 | 6 | 11 | 3 | 21 | 0 | 14 | 8 | 16 | 19 | 22 | 2 |
| QPSK | | 10 | 5 | 13 | 23 | 9 | 17 | 4 | 15 | 1 | 20 | 12 | 7 |

where πₚ(j) is an index of a parity bit group which is punctured j^{th}.

20. The method of claim 14, wherein the pre-set puncturing pattern is defined as in a table presented below when a modulation scheme is BPSK or QPSK:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| BPSK/ | 7/15 | 18 | 6 | 11 | 4 | 0 | 14 | 22 | 9 | 2 | 16 | 20 | 12 |
| | | 7 | 21 | 17 | 3 | 10 | 1 | 15 | 8 | 19 | 5 | 13 | 23 |

where πₚ(j) is an index of a parity bit group which is punctured j^{th}.

21. The method of claim 14, wherein the pre-set puncturing pattern is defined as in
a table presented below when a modulation scheme is 16-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 16 QAM | 7/15 | 4 | 11 | 20 | 18 | 7 | 15 | 13 | 23 | 1 | 9 | 6 | 17 |
| | | 3 | 12 | 19 | 0 | 22 | 8 | 14 | 2 | 21 | 16 | 10 | 5 |

where πₚ(j) is an index of a parity bit group which is punctured j^{th}.

22. The method of claim 14, wherein the pre-set puncturing pattern is defined as in a table presented below when a modulation scheme is 16-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 16 QAM | 7/15 | 4 | 11 | 14 | 6 | 18 | 0 | 22 | 9 | 20 | 2 | 12 | 16 |
| | | 7 | 19 | 15 | 1 | 10 | 5 | 21 | 13 | 3 | 17 | 8 | 23 |

where πₚ(j) is an index of a parity bit group which is punctured j^{th}.

23. The method of claim 14, wherein the pre-set puncturing pattern is defined as in a table presented below when a modulation scheme is 64-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 64 QAM | 7/15 | 11 | 18 | 7 | 0 | 3 | 14 | 21 | 9 | 5 | 23 | 16 | 12 |
| | | 19 | 2 | 8 | 15 | 22 | 10 | 4 | 17 | 1 | 13 | 6 | 20 |

where πₚ(j) is an index of a parity bit group which is punctured j^{th}.

24. The method of claim 14, wherein the pre-set puncturing pattern is defined as in a table presented below when a modulation scheme is 64-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 64 QAM | 7/15 | 18 | 6 | 0 | 13 | 3 | 9 | 21 | 11 | 16 | 20 | 2 | 8 |
| | | 5 | 14 | 17 | 22 | 10 | 19 | 1 | 7 | 15 | 4 | 12 | 23 |

where πₚ(j) is an index of a parity bit group which is punctured j^{th}.

25. The method of claim 14, wherein the pre-set puncturing pattern is defined as in a table presented below when a modulation scheme is 256-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 256 QAM | 7/15 | 4 | 16 | 11 | 20 | 7 | 18 | 0 | 22 | 13 | 2 | 9 | 5 |
| | | 19 | 14 | 8 | 1 | 21 | 10 | 17 | 6 | 15 | 3 | 12 | 23 |

where πₚ(j) is an index of a parity bit group which is punctured j^{th}.

26. The method of claim 14, wherein the pre-set puncturing pattern is defined as in a table presented below when a modulation scheme is 256-QAM:

| | | Order of parity bit group to be punctured, {πₚ(j), 0 ≦ j < Q_{ldpc} = 24} | | | | | | | | | | | |
|---|---|---|---|---|---|---|---|---|---|---|---|---|---|
| Modulation | | πₚ (0) | πₚ (1) | πₚ (2) | πₚ (3) | πₚ (4) | πₚ (5) | πₚ (6) | πₚ (7) | πₚ (8) | πₚ (9) | πₚ (10) | πₚ (11) |
| and Code rate | | πₚ (12) | πₚ (13) | πₚ (14) | πₚ (15) | πₚ (16) | πₚ (17) | πₚ (18) | πₚ (19) | πₚ (20) | πₚ (21) | πₚ (22) | πₚ (23) |
| 256 QAM | 7/15 | 4 | 21 | 6 | 11 | 13 | 18 | 0 | 15 | 2 | 9 | 7 | 22 |
| | | 19 | 1 | 17 | 10 | 14 | 20 | 16 | 5 | 8 | 3 | 12 | 23 |

where πₚ(j) is an index of a parity bit group which is punctured j^{th}.
